(19) United States
(12) Patent Application Publication
(10) Pub. No.: US 2025/0038140 A1
(43) Pub. Date: Jan. 30, 2025

(54) DESIGNING METHOD, SEMICONDUCTOR DEVICE, AND MASK SET

(71) Applicant: KIOXIA CORPORATION, Tokyo (JP)

(72) Inventors: Atsushi TANAKA, Kamakura Kanagawa (JP); Yasushi KAMEDA, Hayama Kanagawa (JP); Yasuyuki KAJITANI, Fujisawa Kanagawa (JP); Shinichi NAKAGAWA, Yokohama Kanagawa (JP); Hiromitsu HARASHIMA, Yokohama Kanagawa (JP)

(73) Assignee: KIOXIA CORPORATION, Tokyo (JP)

(21) Appl. No.: 18/765,462

(22) Filed: Jul. 8, 2024

(30) Foreign Application Priority Data
Jul. 26, 2023 (JP) 2023-121692

(51) Int. Cl. H01L 23/00; G03F 1/76; G06F 30/392; H10B 80/00

(52) U.S. Cl. CPC H01L 24/06; G03F 1/76; G06F 30/392; H01L 24/08; H01L 2224/06177; H01L 2224/08145; H10B 80/00

(57) ABSTRACT

The designing method includes: arranging a plurality of bonding electrode patterns in the kerf regions of the first and second mask; each unplaceable region is identified in each of kerf regions of the first and second mask; removing the bonding electrode patterns placed in the unplaceable region; generating a first pattern group and a second pattern group formed in the kerf regions when the first mask and the second mask are used to perform lithographic exposure while changing a position; and removing the bonding electrode patterns placed in a non-overlapping section in each of the kerf regions of the first mask and the second mask, the non-overlapping section being a plurality of positions of a plurality of the bonding electrode patterns included in the first pattern group and in the second pattern group do not overlap when the first wafer and the second wafer are bonded.

### CROSS-REFERENCE TO RELATED APPLICATIONS

This application is based upon and claims the benefit of Japanese Patent Application No. 2023-121692, filed on Jul. 26, 2023, the entire contents of which are incorporated herein by reference.

### BACKGROUND

### Field

Embodiments described herein relate generally to a designing method, a semiconductor device, and a mask set.

### Description of the Related Art

There has been known a method of manufacturing a semiconductor device in which a first wafer corresponding to a first chip and a second wafer corresponding to a second chip are manufactured and these two wafers are bonded.

### BRIEF DESCRIPTION OF THE DRAWINGS

FIG. 1 is a schematic exploded perspective view illustrating an exemplary configuration of a memory die MD according to an embodiment;

FIG. 2 is a schematic bottom view illustrating an exemplary configuration of a chip C_{M};

FIG. 3 is a schematic bottom view illustrating an exemplary configuration of the chip C_{M};

FIG. 4 is a schematic plan view illustrating an exemplary configuration of a chip C_{P};

FIG. 5 is a schematic cross-sectional view illustrating a configuration of a part of the memory die MD.

FIG. 6 is a schematic cross-sectional view illustrating an enlarged portion in FIG. 5.

FIG. 7 is a schematic cross-sectional view illustrating an enlarged portion in FIG. 6.

FIG. 8 is a schematic bottom view for describing a method of manufacturing the memory die MD according to the embodiment;

FIG. 9 is a schematic bottom view for describing the method of manufacturing the memory die MD according to the embodiment;

FIG. 10 is a schematic cross-sectional view for describing the method of manufacturing the memory die MD according to the embodiment;

FIG. 11 is a schematic cross-sectional view for describing the method of manufacturing the memory die MD according to the embodiment;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic plan view for describing the manufacturing method;

FIG. 16 is a schematic plan view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic perspective view for describing the manufacturing method;

FIG. 21 is a schematic perspective view for describing the manufacturing method;

FIG. 22 is a schematic plan view for describing the manufacturing method;

FIG. 23 is a schematic plan view for describing the manufacturing method;

FIG. 24 is a schematic cross-sectional view illustrating structures of wafers W_{M}, W_{P} in a case where bonding electrodes Pₖ₁ₓ, Pₖ₂ₓ are not disposed in kerf regions R_{K};

FIG. 25 is a schematic cross-sectional view illustrating the structures of the wafers W_{M}, W_{P} in a case where the bonding electrodes Pₖ₁ₓ, Pₖ₂ₓ are disposed in the kerf regions R_{K};

FIG. 26 is a schematic plan view exemplifying a configuration of a part including kerf regions of the wafers W_{M}, W_{P} after bonding;

FIG. 27 is a schematic cross-sectional view exemplifying a configuration of a part including the kerf regions of the wafers W_{M}, W_{P} after bonding;

FIG. 28 is a schematic plan view exemplifying a configuration of a part including the kerf regions of the wafers W_{M}, W_{P} after bonding;

FIG. 29 is a schematic cross-sectional view exemplifying a configuration of a part including the kerf regions of the wafers W_{M}, W_{P} after bonding;

FIG. 30 is a schematic plan view exemplifying a configuration of a part including the kerf regions of the wafers W_{M}, W_{P} after bonding;

FIG. 31 is a schematic cross-sectional view exemplifying a configuration of a part including the kerf regions of the wafers W_{M}, W_{P} after bonding;

FIG. 32 is a flowchart illustrating a processing procedure of design processing for mask data used for manufacturing the bonding electrodes Pₖ₁ₓ, Pₖ₂ₓ in the kerf regions R_{K};

FIG. 33 is a flowchart illustrating an example of a specific processing procedure of Steps S15p, S15m, and S16pm in FIG. 32;

FIG. 34 is a plan view illustrating an example of a bonding electrode part PAR_{X} for X-sides of a kerf region;

FIG. 35 is a plan view illustrating an example of a bonding electrode part PAR_{Y} for Y-sides of the kerf region;

FIG. 36 is a plan view illustrating an example of a bonding electrode part PAR_{CX} for intersecting positions of the kerf region;

FIG. 37 is a plan view illustrating an example of frame data FR_{dat} of masks used for manufacturing the bonding electrodes Pₖ₁ₓ, Pₖ₂ₓ in the kerf regions R_{K};

FIG. 38 is a plan view illustrating a case where the bonding electrode parts PAR_{X}, PAR_{Y}, PAR_{CX} are laid on the frame data FR_{dat} illustrated in FIG. 37;

FIG. 39 is a plan view illustrating an example of frame data FR_{Pdat} of the mask used for manufacturing the bonding electrodes Pₖ₂ₓ in the kerf region R_{K} of the wafer W_{P};

FIG. 40 is a plan view illustrating an example of frame data FR_{Mdat} of the mask used for manufacturing the bonding electrodes Pₖ₁ₓ in the kerf region R_{K} of the wafer W_{M};

FIG. 41 is a plan view illustrating an example of frame data FR_{Pidat} (FR_{Midat}) on which lithography marks used for bonding are placed;

FIG. 42 is a plan view illustrating exemplary placement of the lithography marks in a state where the frame data FR_{Pidat} (FR_{Midat}) in FIG. 41 is subjected to a step-and-repeat process;

FIG. 43 is a plan view illustrating an example of the frame data FR_{Pidat} in a state where a region for TEG and the like is added to the frame data FR_{Pidat} in FIG. 42;

FIG. 44 is a plan view illustrating an example of the frame data FR_{Midat} in a state where a region for TEG and the like is added to the frame data FR_{Midat} in FIG. 42;

FIG. 45 is a plan view illustrating an example of the frame data FR_{Pidat} in a state where a region for frame data is added to the frame data FR_{Pidat} in FIG. 43;

FIG. 46 is a plan view illustrating an example of the frame data FR_{Midat} in a state where a region for frame data is added to the frame data FR_{Midat} in FIG. 44;

FIG. 47 is a plan view illustrating unplaceable regions b_{P1}, b_{P2} attributable to lithography marks in the frame data FR_{Pidat};

FIG. 48 is a plan view illustrating unplaceable regions b_{M1}, b_{M2} attributable to lithography marks in the frame data FR_{Midat};

FIG. 49 is a plan view for describing bonding electrode patterns P_{KX} that are chipped due to a placement prohibited region Rb_{PX} (Rb_{MX}) include ing lithography marks, TEG regions, frame data, or unplaceable regions;

FIG. 50 is a plan view illustrating frame data FR_{PdatSR} in a state where the frame data FR_{Pdat} in FIG. 39 is subjected to the step-and-repeat process;

FIG. 51 is a plan view illustrating frame data FR_{MdatSR} in a state where the frame data FR_{Mdat} in FIG. 40 is subjected to the step-and-repeat process;

FIG. 52 is a plan view illustrating an example of reproduction data FR_{PdatSR2} that has reproduced the state where the frame data FR_{Pdat} in FIG. 39 is subjected to the step-and-repeat process;

FIG. 53 is a plan view illustrating an example of reproduction data FR_{MdatSR2} that has reproduced the state where the frame data FR_{Mdat} in FIG. 40 is subjected to the step-and-repeat process;

FIG. 54 is a plan view illustrating data FR_{PMdif} that illustrates unmatched sections of the bonding electrode patterns P_{KX} in the kerf region after the step-and-repeat process;

FIG. 55 is a plan view illustrating the frame data FR_{Pdat} in which bonding electrode patterns P_{KX} in an unmatched section R_{Kno} are removed from the bonding electrode patterns P_{KX} of the frame data FR_{Pdat} in FIG. 39;

FIG. 56 is a plan view illustrating the frame data FR_{Mdat} in which bonding electrode patterns P_{KX} in an unmatched section R_{Kno} are removed from the bonding electrode patterns P_{KX} of the frame data FR_{Mdat} in FIG. 40;

FIG. 57 is a plan view illustrating the frame data FR_{PdatSR} in a state where the frame data FR_{Pdat} in FIG. 55 is subjected to the step-and-repeat process;

FIG. 58 is a plan view illustrating the frame data FR_{MdatSR} in a state where the frame data FR_{Mdat} in FIG. 56 is subjected to the step-and-repeat process;

FIG. 59 is a plan view illustrating an example of reproduction data FR_{PdatSR2} that has reproduced the state where the frame data FR_{Pdat} in FIG. 55 is subjected to the step-and-repeat process;

FIG. 60 is a plan view illustrating an example of reproduction data FR_{MdatSR2} that has reproduced the state where the frame data FR_{Mdat} in FIG. 56 is subjected to the step-and-repeat process;

FIG. 61 is a schematic plan view exemplifying a configuration of a part of the kerf region R_{K} of a mask after mask data is designed;

FIG. 62 is a schematic plan view exemplifying a configuration of a part of the kerf region R_{K} of a mask after mask data is designed;

FIG. 63 is a plan view conceptually illustrating the frame data FR_{dat} in which frame data Cov_{dat}, lithography marks ALM, and TEG according to a modification are placed; and

FIG. 64 is a plan view conceptually illustrating the frame data FR_{dat} in which the frame data COV_{dat} and the bonding electrode patterns P_{KX} in a kerf region according to a modification are placed.

### DETAILED DESCRIPTION

A designing method according to one embodiment is a designing method of mask set used for lithographic exposure in patterning a plurality of bonding electrodes in a first wafer and a second wafer that are bonded via the plurality of bonding electrodes. The mask set includes a first mask and a second mask. Each of the first wafer and the second wafer includes a plurality of device regions and a kerf region surrounding the plurality of device regions. The plurality of bonding electrodes includes a plurality of first bonding electrodes disposed in the device regions and a plurality of second bonding electrodes disposed in the kerf region and each being in an electrically unconnected state.

The designing method comprises: specifying a size and a shape of the second bonding electrodes; placing a plurality of second bonding electrode patterns corresponding to the second bonding electrodes in the kerf regions of the first mask and the second mask; identifying each unplaceable region where the second bonding electrode is unplaceable in each of the kerf region of the first mask and the kerf region of the second mask; removing, in the kerf region of the first mask, the second bonding electrode patterns placed in the unplaceable region of the first mask; generating a first pattern group in a lithographic exposure region adjacent to other lithographic exposure regions on both sides in a first direction and on both sides in a second direction intersecting with the first direction among nine or more lithographic exposure regions formed when the first mask is used to perform lithographic exposure three times or more while changing a position in the first direction and three times or more while changing a position in the second direction; removing, in the kerf region of the second mask, the second bonding electrode patterns placed in the unplaceable region of the second mask; generating a second pattern group in a lithographic exposure region adjacent to other lithographic exposure regions on both sides in the first direction and on both sides in the second direction among nine or more lithographic exposure regions formed when the second mask is used to perform lithographic exposure three times or more while changing a position in the first direction and three times or more while changing a position in the second direction; and removing the second bonding electrode patterns placed in the non-overlapping section in each of the kerf region of the first mask and the kerf region of the second mask, the non-overlapping section being a plurality of positions of a plurality of the second bonding electrode patterns included in the first pattern group do not overlap with a plurality of positions of a plurality of the second bonding electrode patterns included in the second pattern group when viewed in a direction intersecting with front surfaces of the first wafer and the second wafer when the first wafer and the second wafer are bonded.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor device”, it may mean a die after dicing and may mean a wafer before dicing. In the former case, it may mean a die after packaging and may mean a die before packaging.

In this specification, a “wafer” may include a substrate of silicon (Si) or the like or need not include a substrate of silicon (Si) or the like. Therefore, for example, even when two wafers including a substrate of silicon (Si) or the like are bonded and the substrate is removed from one of the wafers, this configuration still includes the two wafers.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a predetermined direction parallel to a surface of a substrate is referred to as an X-direction, a direction parallel to the surface of the substrate and perpendicular to the X-direction is referred to as a Y-direction, and a direction perpendicular to the surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

When expressions such as “above” and “below” are used in this specification, for example, of two chips included in a memory die, a wafer, and the like, or two wafers, one in which an external pad electrode connectable to a bonding wire is disposed may be an upper side and one in which such an external pad electrode is not disposed may be a lower side. Furthermore, when a configuration included in a memory die, wafers, or the like is mentioned, for example, a direction away from a semiconductor substrate included in a lower side wafer along the above-described Z-direction may be referred to as above and a direction approaching the semiconductor substrate included in the lower side wafer along the Z-direction may be referred to as below. A lower surface and a lower end of a certain configuration may mean a surface and an end portion on a side of a semiconductor substrate included in a lower side wafer of this configuration. An upper surface and an upper end of a certain configuration may mean a surface and an end portion on a side opposite to a semiconductor substrate included in a lower side wafer of this configuration. A surface intersecting with the X-direction or the Y-direction may be referred to as a side surface and the like.

In this specification, when referring to a “width”, a “length”, or the like in a predetermined direction of a configuration, a member, or the like, this may mean a width, a length, or the like in a cross-sectional surface or the like observed with a Scanning electron microscopy (SEM), a Transmission electron microscopy (TEM), or the like.

### Embodiment

### [Structure of Memory Die MD]

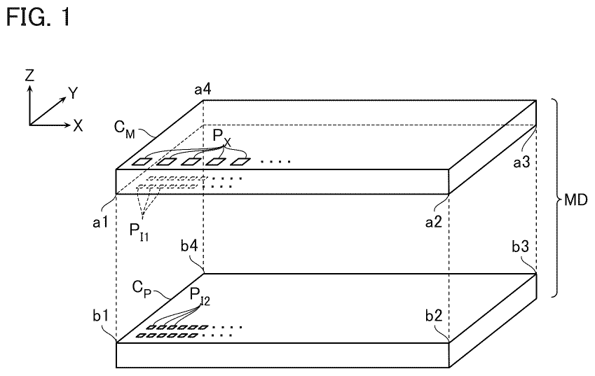

FIG. 1 is a schematic exploded perspective view illustrating an exemplary configuration of a memory die MD according to the embodiment. As illustrated in FIG. 1, the memory die MD includes a chip C_{M} at a memory cell array side and a chip C_{P} at a peripheral circuit side.

On an upper surface of the chip C_{M}, a plurality of external pad electrodes P_{X} connectable to unillustrated bonding wires are disposed. Additionally, a plurality of bonding electrodes Pu are disposed on a lower surface of the chip C_{M}. A plurality of bonding electrodes Piz are disposed on an upper surface of the chip Cp. Hereinafter, regarding the chip C_{M}, a surface on which the plurality of bonding electrodes Pu are disposed is referred to as a front surface, and a surface on which the plurality of external pad electrodes P_{X} are disposed is referred to as a back surface. Regarding the chip C_{P}, a surface on which the plurality of bonding electrodes P_{I2} are disposed is referred to as a front surface, and a surface on a side opposite to the front surface is referred to as a back surface. In the illustrated example, the front surface of the chip C_{P} is disposed above the back surface of the chip C_{P}, and the back surface of the chip C_{M} is disposed above the front surface of the chip C_{M}.

The chip C_{M} and the chip C_{P} are placed such that the front surface of the chip C_{M} is opposed to the front surface of the chip Cp. The respective plurality of bonding electrodes P_{I1} are disposed corresponding to the plurality of bonding electrodes P_{I2} and are placed at positions where the plurality of bonding electrodes P_{I1} can be bonded to the plurality of bonding electrodes P_{I2}. The bonding electrodes P_{I1} and the bonding electrodes P_{I2} function as bonding electrodes for bonding the chip C_{M} and the chip C_{P} and electrically conducting them.

Note that in the example of FIG. 1, corner portions a1, a2, a3, a4 of the chip C_{M} correspond to corner portions b1, b2, b3, b4 of the chip C_{P}, respectively.

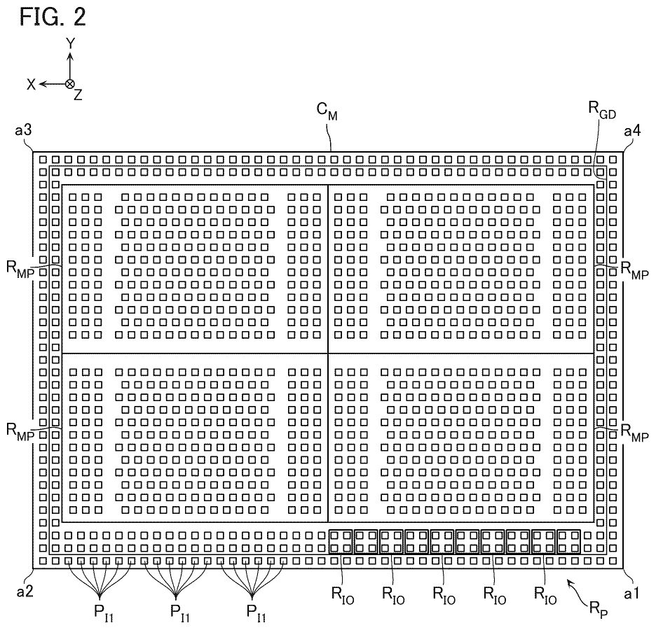

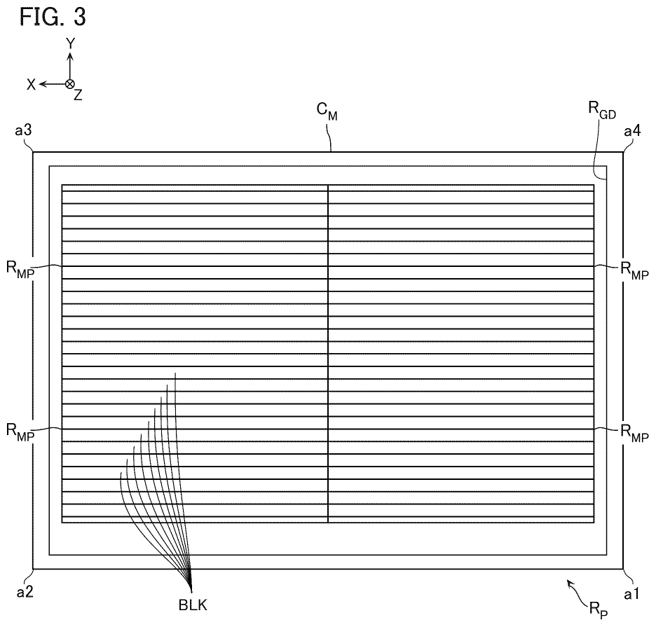

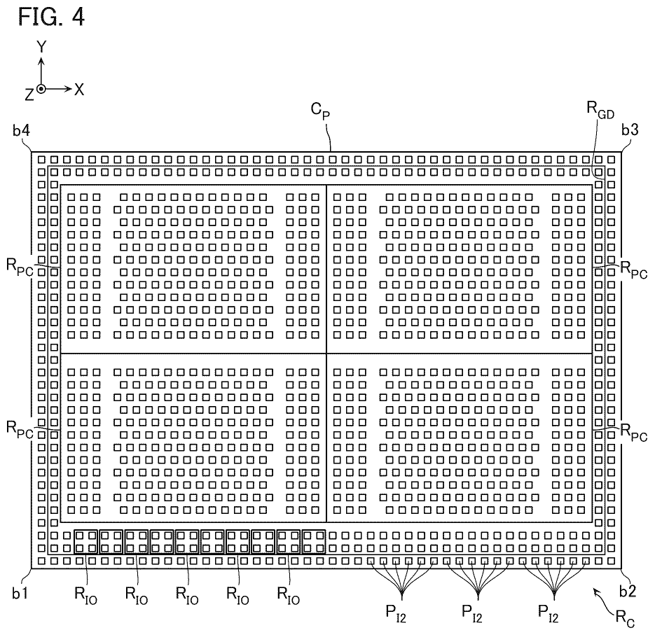

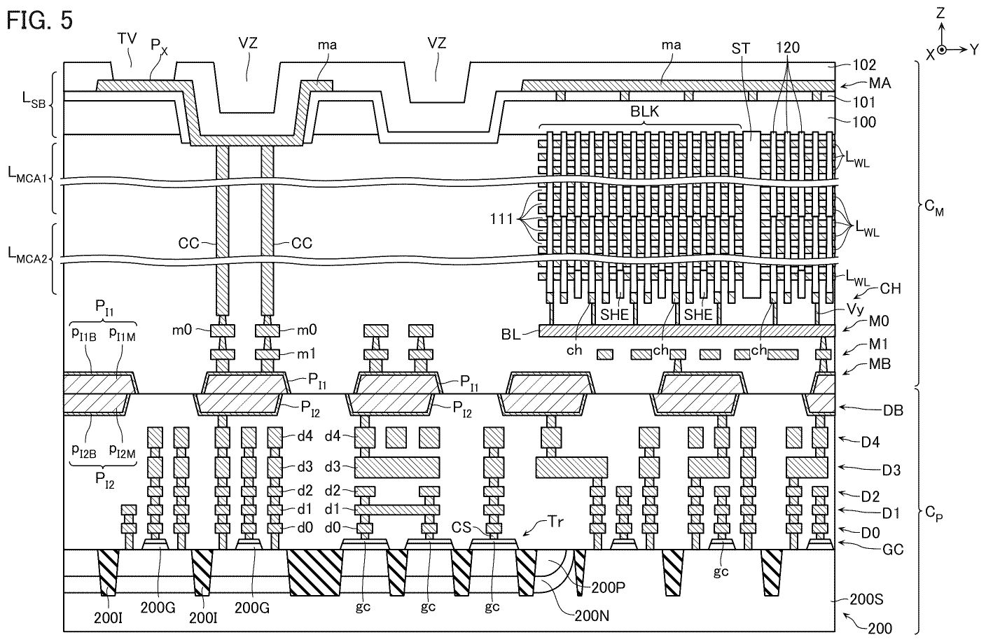

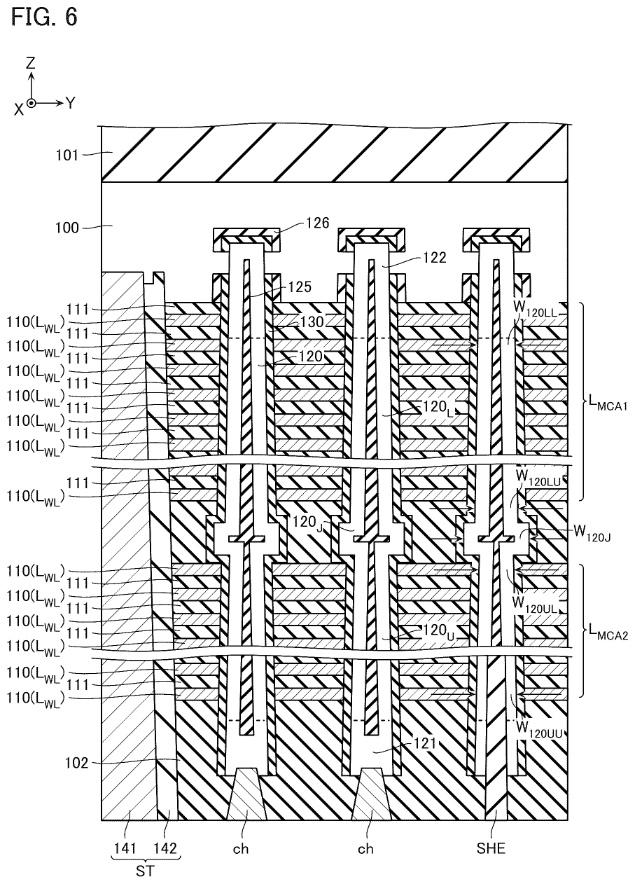

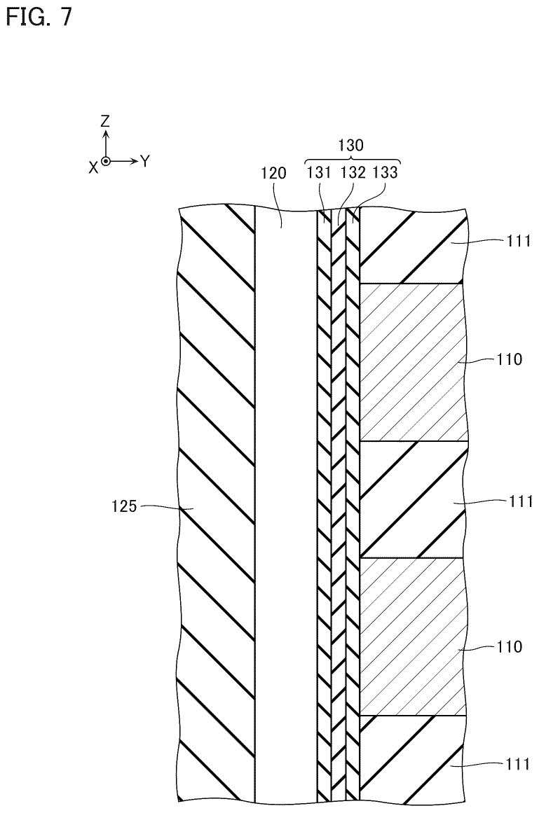

FIG. 2 and FIG. 3 are schematic bottom views illustrating an exemplary configuration of the chip C_{M}. FIG. 3 omits a part of the configurations, such as the bonding electrodes Pu. FIG. 4 is a schematic plan view illustrating an exemplary configuration of the chip Cp. FIG. 5 is a schematic cross-sectional view illustrating a configuration of a part of the memory die MD. FIG. 6 is a schematic cross-sectional view illustrating an enlarged portion in FIG. 5. FIG. 7 is a schematic cross-sectional view illustrating an enlarged portion in FIG. 6. Although FIG. 7 illustrates a Y-Z cross-sectional surface, a structure similar to that in FIG. 7 is also observed when a cross-sectional surface other than the Y-Z cross-sectional surface (for example, an X-Z cross-sectional surface) along a central axis of a semiconductor layer 120 is observed.

### [Structure of Chip C_{M}]

For example, as illustrated in FIG. 2, the chip C_{M} includes four memory plane regions R_{MP} arranged in the X-direction and the Y-direction. Additionally, the chip C_{M} includes a peripheral region R_{P} disposed on one end side in the Y-direction with respect to the four memory plane regions R_{MP}. The peripheral region R_{P} includes a plurality of input/output regions Rio arranged in the X-direction. In the chip C_{M}, a guard ring region R_{GD} surrounding these four memory plane regions R_{MP} and the plurality of input/output regions Rio is disposed.

For example, as illustrated in FIG. 5, the chip C_{M} includes a substrate body structure L_{SB}, memory cell array layers L_{MCA1}, L_{MCA2} disposed under the substrate body structure L_{SB}, an electrode layer CH disposed below the memory cell array layers L_{MCA1}, L_{MCA2}, and a plurality of wiring layers M0, M1, MB disposed below the electrode layer CH. Each of the memory cell array layers L_{MCA1}, L_{MCA2} includes a plurality of word line layers L_{WL} arranged in the Z-direction. Between the respective adjacent plurality of word line layers L_{WL} arranged in the Z-direction, interlayer insulating layers 111 of silicon oxide (SiO₂) or the like are disposed.

[Structure of Substrate Body Structure L_{SB} in Chip C_{M}]

For example, as illustrated in FIG. 5, the substrate body structure L_{SB} includes a conductive layer 100 disposed on an upper surface of the memory cell array layer L_{MCA1}, an insulating layer 101 disposed on an upper surface of the conductive layer 100, a back side wiring layer MA disposed on an upper surface of the insulating layer 101, and an insulating layer 102 disposed on an upper surface of the back side wiring layer MA.

The conductive layer 100 may include, for example, a semiconductor layer of, for example, silicon (Si) into which N-type impurities, such as phosphorus (P), or P-type impurities, such as boron (B), are injected, may include a metal, such as tungsten (W), or may include silicide, such as tungsten silicide (WSi).

The conductive layer 100 functions as a part of a source line of a NAND flash memory. Four conductive layers 100 are disposed corresponding to the four memory plane regions R_{MP} (FIG. 2) arranged in the X-direction and the Y-direction. A region VZ that does not include the conductive layer 100 is disposed at end portions in the X-direction and the Y-direction of the memory plane region R_{MP}.

The insulating layer 101 contains, for example, silicon oxide (SiO₂) or the like.

The back side wiring layer MA includes a plurality of wirings ma. These plurality of wirings ma may contain, for example, aluminum (Al) or the like.

Parts of the plurality of wirings ma function as a part of the source line of the NAND flash memory. Four such wirings ma are disposed corresponding to the four memory plane regions R_{MP} (FIG. 2) arranged in the X-direction and the Y-direction. These wirings ma are electrically connected to the respective conductive layers 100.

In addition, parts of the plurality of wirings ma function as the external pad electrodes P_{X}. A plurality of these wirings ma are disposed corresponding to the plurality of input/output regions Rio (FIG. 2) arranged in the X-direction. These wirings ma are connected to via-contact electrodes CC in the memory cell array layers L_{MCA1}, L_{MCA2} in the region VZ that does not include the conductive layer 100. A part of the wiring ma is exposed to an outside of the memory die MD via an opening TV provided in the insulating layer 102.

The insulating layer 102 is, for example, a passivation layer that contains a resin material, such as polyimide, in an upper layer portion.

[Structure of Memory Cell Array Layers L_{MCA1}, L_{MCA2} Of Chip C_{M} in Memory Plane Region R_{MP}]

For example, as illustrated in FIG. 3, the memory cell array layers L_{MCA1}, L_{MCA2} include a plurality of memory blocks BLK arranged in the Y-direction. As illustrated in FIG. 5, an inter-block structure ST is disposed between two memory blocks BLK adjacent in the Y-direction.

For example, as illustrated in FIG. 6, the memory block BLK includes a plurality of conductive layers 110 arranged in the Z-direction corresponding to the plurality of word line layers L_{WL}, a plurality of semiconductor layers 120 extending in the Z-direction, and a respective plurality of gate insulating films 130 disposed between the plurality of conductive layers 110 and the plurality of semiconductor layers 120.

The conductive layer 110 has an approximate plate shape extending in the X-direction. The conductive layer 110 may include, for example, a stacked film of a barrier conductive film of titanium nitride (TiN) or the like and a metal film of tungsten (W) or the like. The conductive layer 110 may contain, for example, polycrystalline silicon containing impurities, such as phosphorus (P) or boron (B).

Among the plurality of conductive layers 110, one or a plurality of conductive layers 110 positioned at an uppermost layer function as a select gate line of the NAND flash memory and gate electrodes of a plurality of select transistors connected to the select gate line. These plurality of conductive layers 110 are electrically independent for each memory block BLK.

A plurality of conductive layers 110 positioned below these conductive layers 110 function as a word line of the NAND flash memory and gate electrodes of a plurality of memory cells (memory transistors) connected to the word line. These plurality of conductive layers 110 are each electrically independent for each memory block BLK.

In addition, one or a plurality of conductive layers 110 positioned below these conductive layers 110 function as a select gate line of the NAND flash memory and gate electrodes of a plurality of select transistors connected to the select gate line. A width in the Y-direction of these plurality of conductive layers 110 is smaller than that of the other conductive layers 110. Between two conductive layers 110 adjacent in the Y-direction, an insulating layer SHE of, for example, silicon oxide (SiO₂) is disposed.

The semiconductor layers 120 are arranged in the X-direction and the Y-direction in a predetermined pattern.

The semiconductor layers 120 function as memory cells and channel regions of the select transistors of the NAND flash memory. The semiconductor layer 120 contains, for example, polycrystalline silicon (Si) or the like. The semiconductor layer 120 has an approximately cylindrical shape and has a center portion including an insulating layer 125 of silicon oxide or the like.

The semiconductor layer 120 includes a semiconductor region 1201 included in the memory cell array layer L_{MCA1} and a semiconductor region 120_{U} included in the memory cell array layer L_{MCA2}. In addition, the semiconductor layer 120 includes a semiconductor region 120_{J} connected to a lower end of the semiconductor region 120_{L} and an upper end of the semiconductor region 120_{U}, an impurity region 122 connected to an upper end of the semiconductor region 120_{L}, and an impurity region 121 connected to a lower end of the semiconductor region 120_{L}.

The semiconductor region 120 has an approximately cylindrical shape extending in the Z-direction. The semiconductor region 120_{L} has an outer peripheral surface surrounded by a plurality of conductive layers 110 each included in the memory cell array layer L_{MCA1} and is opposed to these plurality of conductive layers 110. A width W_{120LL} in a radial direction of an upper end portion of the semiconductor region 120_{L} is smaller than a width W_{120LU} in the radial direction of a lower end portion of the semiconductor region 120_{L}.

The semiconductor region 120_{U} has an approximately cylindrical shape extending in the Z-direction. The semiconductor region 120_{U} has an outer peripheral surface surrounded by a plurality of conductive layers 110 each included in the memory cell array layer L_{MCA2} and is opposed to these plurality of conductive layers 110. A width W_{120UL} in the radial direction of an upper end portion of the semiconductor region 120_{U} is smaller than a width W_{120UU} in the radial direction of a lower end portion of the semiconductor region 120_{U} and the width W_{120LU} described above.

The semiconductor region 120_{J} is disposed below the plurality of conductive layers 110 each included in the memory cell array layer L_{MCA1} and above the plurality of conductive layers 110 included in the memory cell array layer L_{MCA2}. A width W_{120J} in the radial direction of the semiconductor region 120j is larger than the widths W_{120LU}, W_{120UU} described above.

The impurity region 122 is connected to the above-described conductive layer 100. In the example of FIG. 6, a boundary line between the semiconductor region 120_{L} and the impurity region 122 is indicated by a dashed line. The impurity region 122 contains, for example, N-type impurities, such as phosphorus (P) or P-type impurities, such as boron (B).

The impurity region 121 contains, for example, N-type impurities, such as phosphorus (P). In the example of FIG. 6, a boundary line between the semiconductor region 120_{U} and the impurity region 121 is indicated by a dashed line.

The impurity region 121 is connected to a bit line BL via a via-contact electrode ch and a via-contact electrode Vy (FIG. 5).

The gate insulating film 130 has an approximately cylindrical shape that covers an outer peripheral surface of the semiconductor layer 120. As illustrated in FIG. 7, for example, the gate insulating film 130 includes a tunnel insulating film 131, an electric charge accumulating film 132, and a block insulating film 133, which are stacked between the semiconductor layer 120 and the conductive layers 110. The tunnel insulating film 131 and the block insulating film 133 contain, for example, silicon oxide (SiO₂) or the like. The electric charge accumulating film 132 includes, for example, a film configured to accumulate electric charges of silicon nitride (SiN) or the like. The tunnel insulating film 131, the electric charge accumulating film 132, and the block insulating film 133, which have approximately cylindrical shapes, extend in the Z-direction along the outer peripheral surface of the semiconductor layer 120 excluding a contact portion of the semiconductor layer 120 and the conductive layer 100. As illustrated in FIG. 6, an insulating layer 126 of silicon oxide (SiO₂) or the like is disposed between the gate insulating film 130 and the conductive layer 100. FIG. 7 illustrates an example in which the gate insulating film 130 includes the electric charge accumulating film 132 of silicon nitride or the like. However, the gate insulating film 130 may include, for example, a floating gate of polycrystalline silicon containing N-type or P-type impurities or the like.

As illustrated in FIG. 6, for example, the inter-block structure ST includes a conductive layer 141 extending in the Z-direction and the X-direction and an insulating layer 142 disposed on a side surface of the conductive layer 141. The conductive layer 141 is connected to the conductive layer 100. The conductive layer 141 may include, for example, a stacked film of a barrier conductive film of, for example, titanium nitride (TiN) and a metal film of, for example, tungsten (W), or the like. The conductive layer 141 functions as, for example, a part of the source line of the NAND flash memory.

[Structure of Memory Cell Array Layers L_{MCA1}, L_{MCA2} Of Chip C_{M} in Peripheral Region R_{P}]

For example, as illustrated in FIG. 5, the peripheral region R_{P} includes a plurality of via-contact electrodes CC corresponding to the external pad electrode P_{X}. These plurality of via-contact electrodes CC have upper ends connected to the wiring ma that functions as the external pad electrode P_{X}.

### [Structure of Electrode Layer CH in Chip C_{M}]

The electrode layer CH includes a plurality of via-contact electrodes ch. These plurality of via-contact electrodes ch are, for example, electrically connected to at least one of configurations in the memory cell array layers L_{MCA1}, L_{MCA2} and configurations in the chip Cp. These plurality of via-contact electrodes ch may include, for example, a stacked film of a barrier conductive film of, for example, titanium nitride (TiN) and a metal film of, for example, tungsten (W), or the like. The via-contact electrodes ch are disposed corresponding to the plurality of semiconductor layers 120 and connected to lower ends of the plurality of semiconductor layers 120.

### [Structures of Wiring Layers M0, M1, MB in Chip C_{M}]

For example, as illustrated in FIG. 5, a plurality of wirings included in the wiring layers M0, M1, MB are, for example, electrically connected to at least one of the configurations in the memory cell array layers L_{MCA1}, L_{MCA2} and the configurations in the chip Cp.

The wiring layer M0 includes a plurality of wirings m0. These plurality of wirings m0 may include, for example, a stacked film of a barrier conductive film of, for example, titanium nitride (TiN) and a metal film of, for example, copper (Cu), or the like. Note that parts of the plurality of wirings m0 function as the bit lines BL. For example, the bit lines BL are arranged in the X-direction and extend in the Y-direction.

As illustrated in FIG. 5, for example, the wiring layer M1 includes a plurality of wirings m1. These plurality of wirings m1 may include, for example, a stacked film of a barrier conductive film of, for example, titanium nitride (TiN) and a metal film of, for example, tungsten (W), or the like.

The wiring layer MB includes a plurality of bonding electrodes P_{I1}. These plurality of bonding electrodes P_{I1} may include, for example, a stacked film of a barrier conductive film pus of, for example, titanium nitride (TiN) and a metal film p_{I1M} of, for example, copper (Cu), or the like.

### [Structure of Chip C_{P}]

For example, as illustrated in FIG. 4, the chip C_{P} includes four peripheral circuit regions R_{PC} arranged in the X-direction and the Y-direction corresponding to the memory plane regions R_{MP}. Additionally, the chip C_{P} includes a circuit region R_{C} disposed in a region opposed to the peripheral region R_{P}. The circuit region R_{C} includes a plurality of input/output regions Rio arranged in the X-direction. In the chip Ce, a guard ring region R_{GD} surrounding these four peripheral circuit regions R_{PC} and the input/output regions Rio is disposed.

In addition, for example, as illustrated in FIG. 5, the chip C_{P} includes a semiconductor substrate 200, an electrode layer GC disposed above the semiconductor substrate 200, and wiring layers D0, D1, D2, D3, D4, DB disposed above the electrode layer GC.

### [Structure of Semiconductor Substrate 200 in Chip C_{P}]

The semiconductor substrate 200 contains, for example, P-type silicon (Si) containing P-type impurities, such as boron (B). On a surface of the semiconductor substrate 200, for example, an N-type well region 200N containing N-type impurities, such as phosphorus (P), a P-type well region 200P containing P-type impurities, such as boron (B), a semiconductor substrate region 200S in which the N-type well region 200N or the P-type well region 200P is not disposed, and insulating regions 200I are disposed. The N-type well region 200N, the P-type well region 200P, and the semiconductor substrate region 200S each function as parts of a plurality of transistors Tr constituting a peripheral circuit, parts of a plurality of capacitors, and the like.

### [Structure of Electrode Layer GC in Chip C_{P}]

For example, as illustrated in FIG. 5, the electrode layer GC is disposed on an upper surface of the semiconductor substrate 200 via insulating layers 200G. The electrode layer GC includes a plurality of electrodes gc opposed to the surface of the semiconductor substrate 200 in the Z-direction. Additionally, the respective regions in the semiconductor substrate 200 and the plurality of electrodes gc included in the electrode layer GC are connected to respective via-contact electrodes CS.

The N-type well region 200N, the P-type well region 200P, and the semiconductor substrate region 200S in the semiconductor substrate 200 each function as channel regions of the plurality of transistors Tr constituting the peripheral circuit, ones of electrodes of the plurality of capacitors, and the like.

The plurality of electrodes gc included in the electrode layer GC each function as gate electrodes of the plurality of transistors Tr constituting the peripheral circuit, the others of the electrodes of the plurality of capacitors, and the like.

The via-contact electrodes CS extend in the Z-direction and have lower ends connected to an upper surface of the semiconductor substrate 200 or upper surfaces of the electrodes gc. In connecting parts between the via-contact electrodes CS and the semiconductor substrate 200, impurity regions containing N-type impurities or P-type impurities are disposed. The via-contact electrodes CS may include, for example, a stacked film of a barrier conductive film of, for example, titanium nitride (TiN) and a metal film of, for example, tungsten (W), or the like.

### [Structures of Wiring Layers D0, D1, D2, D3, D4, DB in Chip C_{P}]

For example, as illustrated in FIG. 5, a plurality of wirings included in the wiring layers D0, D1, D2, D3, D4, DB are, for example, electrically connected to at least one of the configurations in the memory cell array layers L_{MCA1}, L_{MCA2} and the configurations in the chip Cp.

The wiring layers DO, D1, D2 include a plurality of wirings d0, d1, d2, respectively. These plurality of wirings d0, d1, d2 may include, for example, a stacked film of a barrier conductive film of, for example, titanium nitride (TiN) and a metal film of, for example, tungsten (W), or the like.

The wiring layers D3, D4 include a plurality of wirings d3, d4, respectively. These plurality of wirings d3, d4 may include, for example, a stacked film of a barrier conductive film of, for example, titanium nitride (TiN) and a metal film of, for example, copper (Cu), or the like.

The wiring layer DB includes a plurality of bonding electrodes P_{I2}. These plurality of bonding electrodes P_{I2} may include, for example, a stacked film of a barrier conductive film p_{I2B} of, for example, titanium nitride (TiN) and a metal film p_{I2M} of, for example, copper (Cu), or the like.

Here, when the metal films p_{I1M}, P_{I2M} of, for example, copper (Cu) are used for the bonding electrode P_{I1} and the bonding electrode P_{I2}, the metal film p_{I1M} and the metal film p_{I2M} are integrated, making it difficult to confirm a mutual boundary. However, a bonding structure can be confirmed by distortion of a shape of the bonding electrode P_{I1} bonded to the bonding electrode P_{I2} due to positional shift of the bonding and by the positional shift (generation of discontinuous sections on side surfaces) of the barrier conductive films p_{I1B}, P_{I2B}. When the bonding electrode P_{I1} and the bonding electrode P_{I2} are formed by a damascene method, the respective side surfaces have tapered shapes. In view of this, a shape of a cross-sectional surface along the Z-direction in a part where the bonding electrode P_{I1} and the bonding electrode P_{I2} are bonded is a non-rectangular shape without sidewalls becoming linear. In addition, when the bonding electrode P_{I1} and the bonding electrode P_{I2} are bonded, a structure is provided in which a barrier metal covers a bottom surface, side surfaces, and an upper surface of each Cu forming the bonding electrode P_{I1} and the bonding electrode P_{I2}. In contrast to this, in a wiring layer using general Cu, an insulating layer (for example, SiN or SiCN) having an oxidation prevention function of Cu is disposed on an upper surface of the Cu, and a barrier metal is not disposed. In view of this, even when positional shift of bonding is not generated, distinction from a general wiring layer is possible.

### [Manufacturing Method]

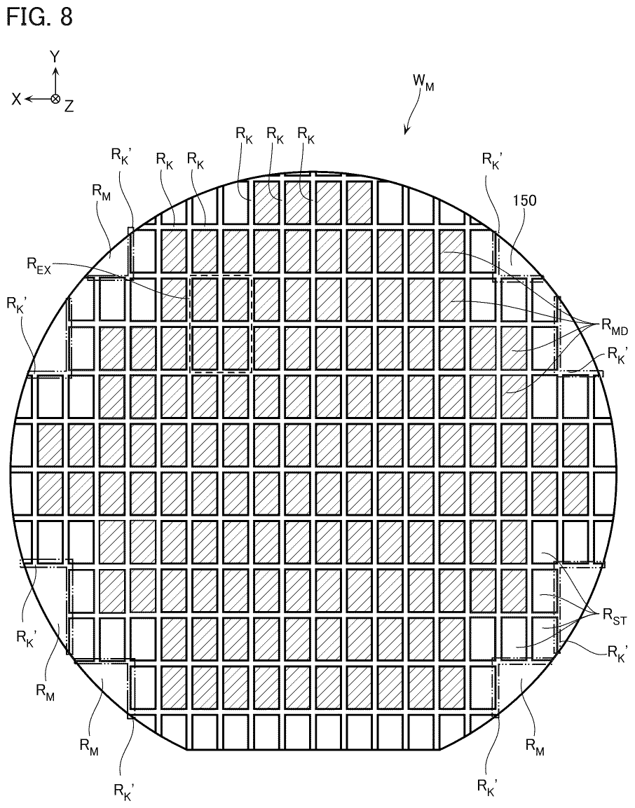

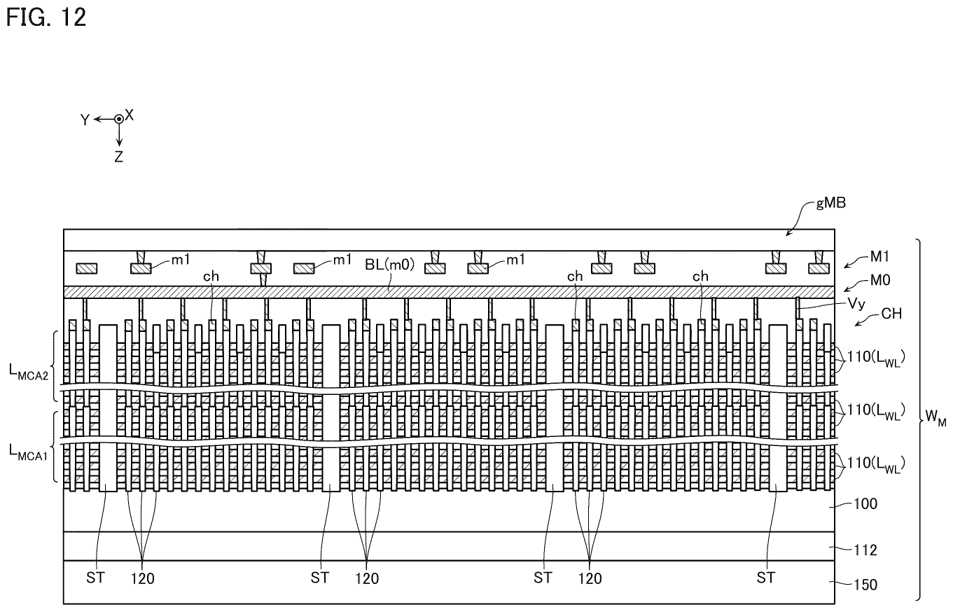

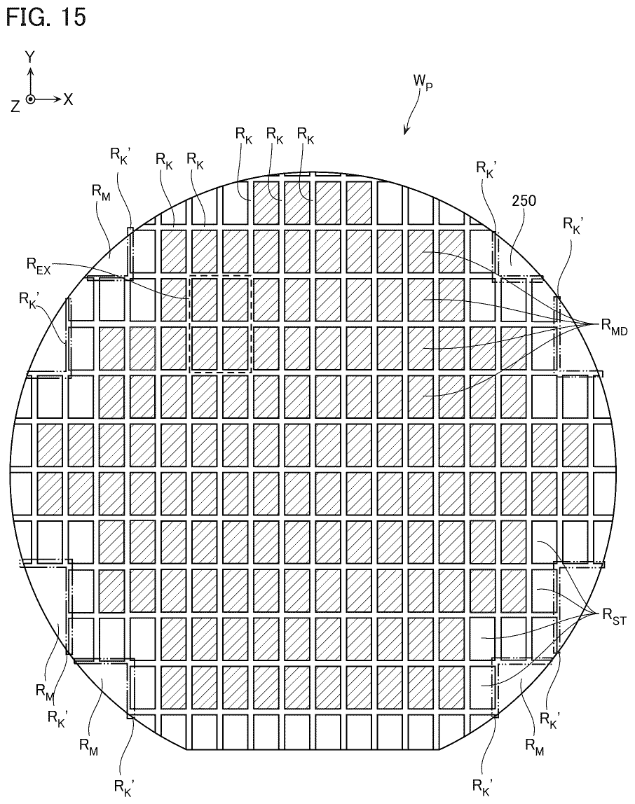

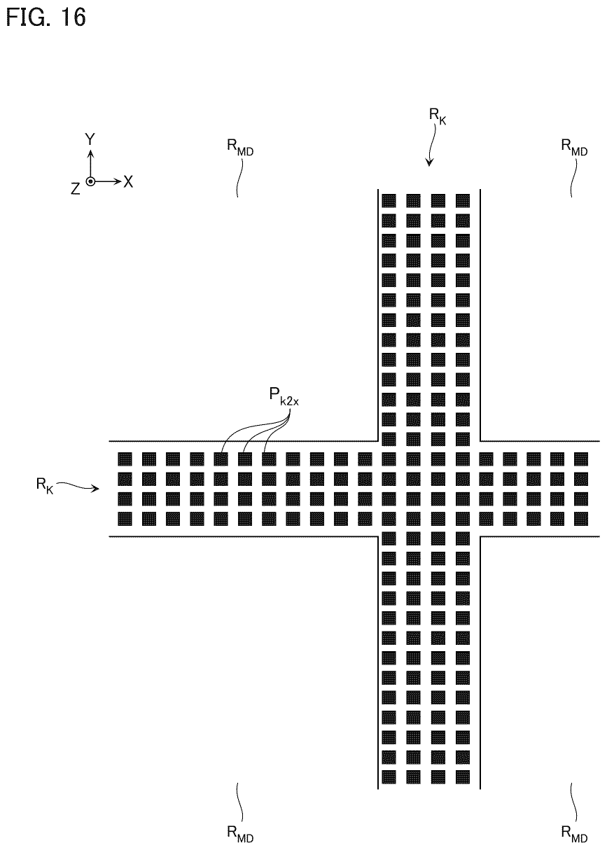

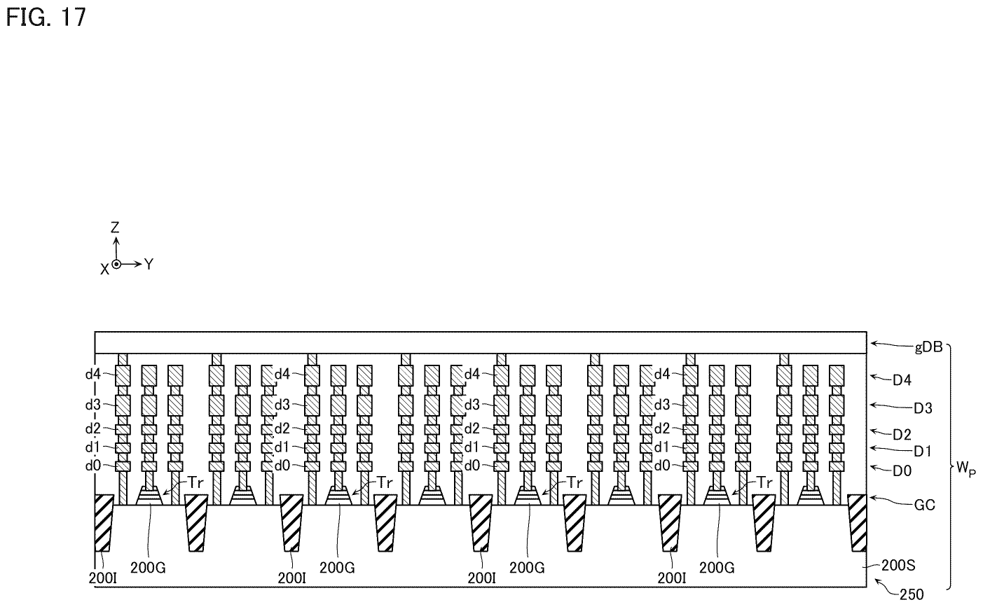

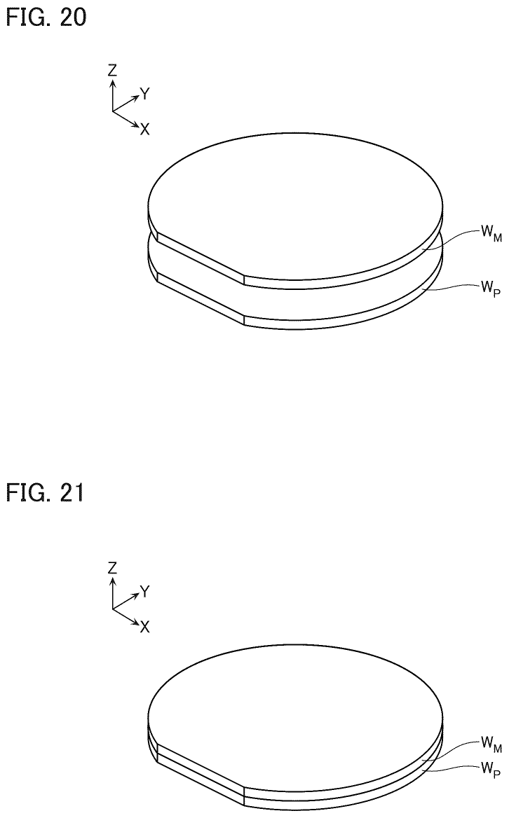

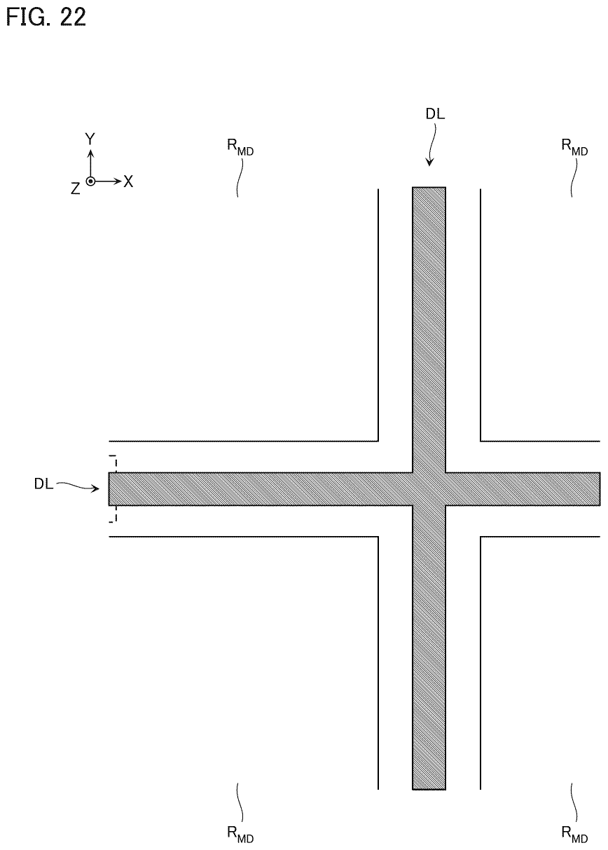

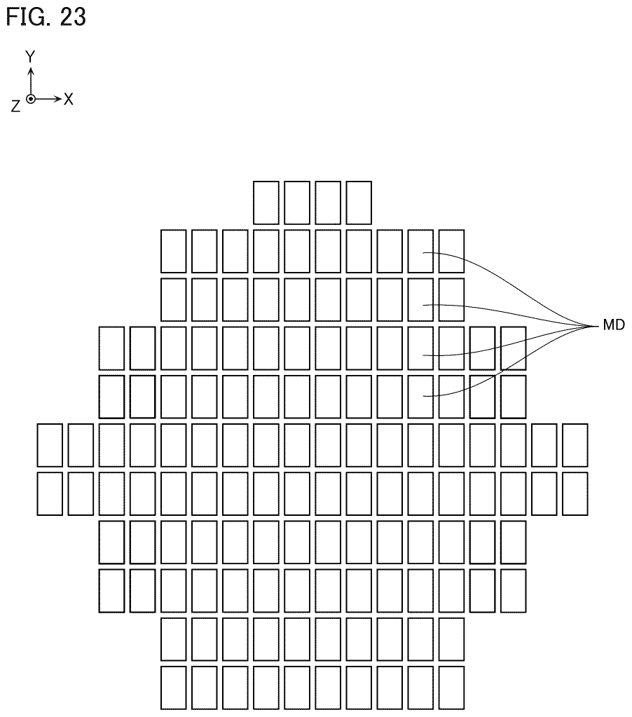

Next, with reference to FIG. 8 to FIG. 23, a method of manufacturing the memory die MD is described. FIG. 8 to FIG. 11 are schematic bottom views for describing the method of manufacturing the memory die MD according to the embodiment. FIG. 12 to FIG. 14 are schematic cross-sectional views for describing the manufacturing method. FIG. 15 and FIG. 16 are schematic plan views for describing the manufacturing method. FIG. 17 to FIG. 19 are schematic cross-sectional views for describing the manufacturing method. FIG. 20 and FIG. 21 are schematic perspective views for describing the manufacturing method. FIG. 22 and FIG. 23 are schematic plan views for describing the manufacturing method. Note that FIG. 12 to FIG. 14 illustrate a cross-sectional surface corresponding to FIG. 6. FIG. 17 to FIG. 19 illustrate a cross-sectional surface corresponding to FIG. 5. In the drawings referenced below, hatching is added to the plan views as appropriate to easily view the figures. The hatching added to the plan views is not necessarily related to the materials and characteristics of the components provided with the hatching.

In manufacturing the memory die MD according to the embodiment, a wafer W_{M} corresponding to the chip C_{M} and a wafer W_{P} corresponding to the chip C_{P} are manufactured (see FIG. 20), these two wafers W_{M}, W_{P} are bonded (see FIG. 21), and after the back side wiring layer MA (FIG. 5) and the like are formed, singulation by dicing is performed (see FIG. 23).

### [Manufacturing Method of Wafer W_{M}]

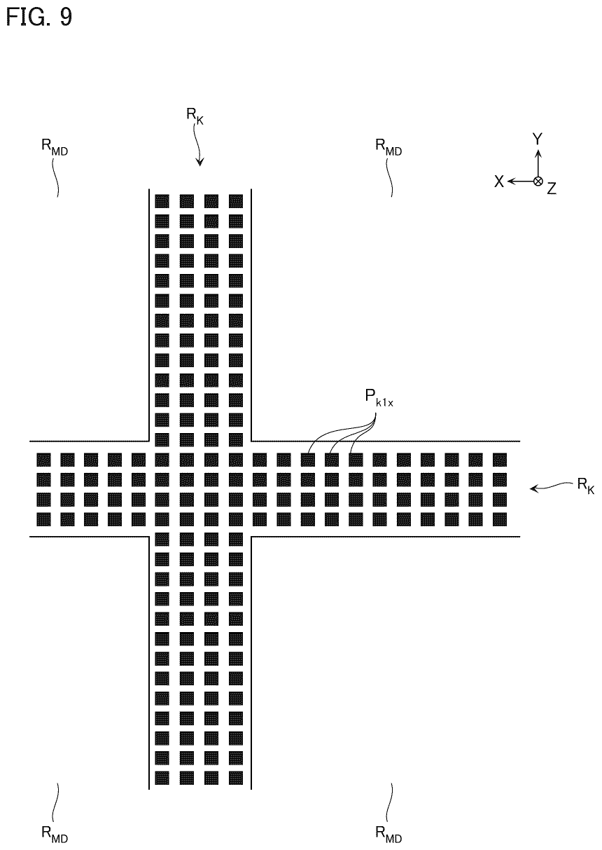

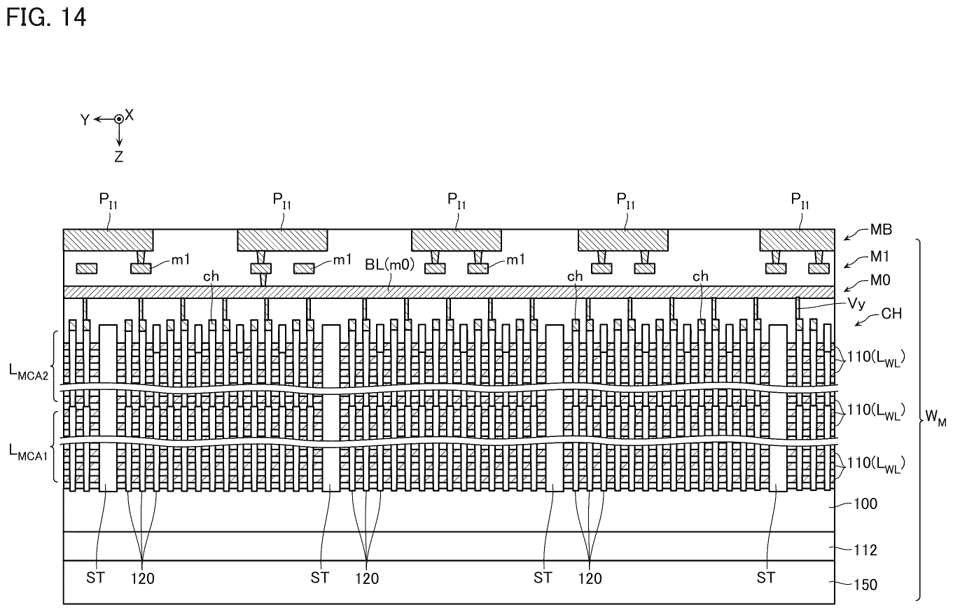

FIG. 8 illustrates a surface of a semiconductor substrate 150 corresponding to the wafer W_{M}. FIG. 9 illustrates an enlarged portion in FIG. 8. As illustrated in FIG. 8, a plurality of device regions R_{MD} and structure body regions R_{ST} arranged in the X-direction and the Y-direction, a kerf region Rx disposed between these plurality of device regions R_{MD} and structure body regions R_{ST}, a kerf region R_{K}′ disposed on one side in the X-direction or the Y-direction of the structure body regions R_{ST}, and a margin region R_{M} are disposed on the surface of the semiconductor substrate 150. An insulating layer 112 of silicon oxide (SiO₂) or the like is disposed between the semiconductor substrate 150 and the conductive layer 100 (see FIG. 14).

The device region R_{MD} is an approximately rectangular region that becomes a part of the memory die MD after dicing and includes a configuration corresponding to the chip C_{M}. The device region R_{MD} is adjacent to another device region R_{MP} or a structure body region R_{ST} each on both sides in the X-direction and each on both sides in the Y-direction.

The structure body regions R_{ST} are regions formed simultaneously with the device regions R_{MD} in manufacturing the wafer W_{M} and include configurations approximately similar to those of the device regions R_{MD}. However, the structure body region R_{ST} is not generally used as a part of the memory die MD after dicing. The structure body region R_{ST} is adjacent to a device region R_{MD} or another structure body region R_{ST} on one side in the X-direction and on one side in the Y-direction. Parts of structure body regions R_{ST} are formed in an approximately rectangular shape similarly to the device regions R_{MD} and have the same area as the device regions R_{MD}. These structure body regions R_{ST} are adjacent to the margin region R_{M} in the X-direction, the Y-direction, or a diagonal direction in an X-Y plane via the kerf region R_{K}′. A distance of these structure body regions R_{ST} to the margin region R_{M} is smaller than the smaller of a width in the X-direction of the device regions R_{MD} and a width in the Y-direction of the device regions R_{MD}. The other structure body regions R_{ST} have a part of an outer periphery along an outer periphery of the wafer W_{M} and has a smaller area than the device regions R_{MD}.

The kerf region Rx is a region including dicing lines. Configurations in the kerf region Rx are not used for inputting and outputting a voltage to a memory cell array or for inputting and outputting a data signal or other signals to the memory cell array. The kerf region Rx includes, for example, test patterns used for performing evaluations and analyses of failures and the like that occur in manufacturing and alignment marks used as fiducial marks for positioning the configurations in the wafer W_{M} in the X-Y plane, which are used for manufacturing the memory die MD. For example, as illustrated in FIG. 9, a plurality of bonding electrodes Pₖ₁ₓ (second bonding electrodes) used for bonding the two wafers W_{M}, W_{P} are disposed on the wiring layer MB in the kerf region R_{K}. These plurality of bonding electrodes Pₖ₁ₓ are electrically unconnected (in a floating state). All of these plurality of bonding electrodes Pₖ₁ₓ are placed at positions that overlap with any of the bonding electrodes Pₖ₂ₓ (FIG. 16) when viewed in the Z-direction after the wafers W_{M}, W_{P} are bonded.

The kerf region R_{K}′ is basically configured similarly to the kerf region R_{K}. However, the number of bonding electrodes Pₖ₁ₓ placed on the wiring layer MB in the kerf region R_{K}′ is less than the number of bonding electrodes Pₖ₁ₓ placed on the wiring layer MB in the kerf region R_{K}. In addition, an area of the bonding electrodes Pₖ₁ₓ per unit area on the wiring layer MB in the kerf region R_{K}′ is smaller than an area of the bonding electrodes Pₖ₁ₓ per unit area on the wiring layer MB in the kerf region R_{K}. The kerf region R_{K}′ is positioned at an outer periphery of the entire plurality of structure body regions R_{ST} arranged in the X-direction and the Y-direction. The kerf region R_{K}′ is disposed between the structure body regions R_{ST} and the margin region R_{M}.

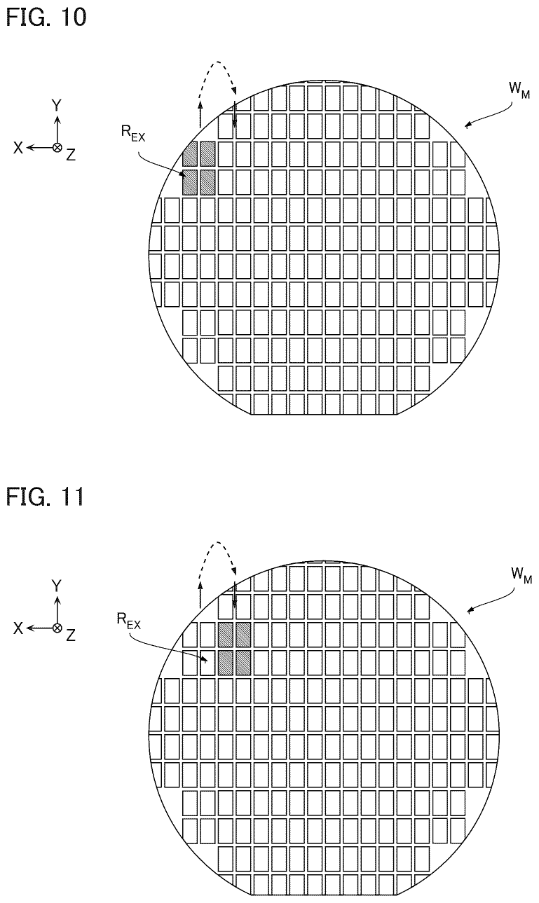

The margin region R_{M} is a region where lithographic exposure is not performed in a process described later with reference to FIG. 10 and FIG. 11.

Next, patterning of the bonding electrodes P_{I1}, Pₖ₁ₓ used for bonding the wafers W_{M}, W_{P} is described. For example, as illustrated in FIG. 10 and FIG. 11, a plurality of lithographic exposure regions R_{EX} are formed on the wafer W_{M} using a mask used for lithographic exposure to perform lithographic exposure, for example, a plurality of times while changing a position in the X-direction and a plurality of times while changing a position in the Y-direction. Then, in the lithographic exposure regions R_{EX}, a plurality of bonding electrode patterns corresponding to the plurality of bonding electrodes Pu are transferred to the device regions R_{MD} and the structure body regions R_{ST}, and a plurality of bonding electrode patterns corresponding to the plurality of bonding electrodes Pₖ₁ₓ are transferred to the kerf regions R_{K}, R_{K′}. Note that lithographic exposure is a process of printing circuits and the like to the wafers W_{M}, W_{P} by irradiating the wafers W_{M}, W_{P} with light, such as ultraviolet rays, through a mask. This lithographic exposure may be a stepper (step-and-repeat) type of lithographic exposure in which all patterns in a mask are transferred onto a wafer at a time by exposure to light or may be a scan (step-and-scan) type of lithographic exposure in which patterns in a mask are scanned and gradually transferred onto a wafer by exposure to light. For example, as illustrated in FIG. 8, in the embodiment, an example in which each of the lithographic exposure regions R_{EX} includes four device regions R_{MD} arranged in the X-direction and the Y-direction is described.

For example, as illustrated in FIG. 12 to FIG. 14, the bonding electrodes Pu, Pₖ₁ₓ are formed by a damascene process.

For example, as illustrated in FIG. 12, an insulating layer gMB of silicon oxide (SiO₂) or the like is formed on a surface of the wiring layer M1. This process is performed by, for example, a method, such as Chemical Vapor Deposition (CVD).

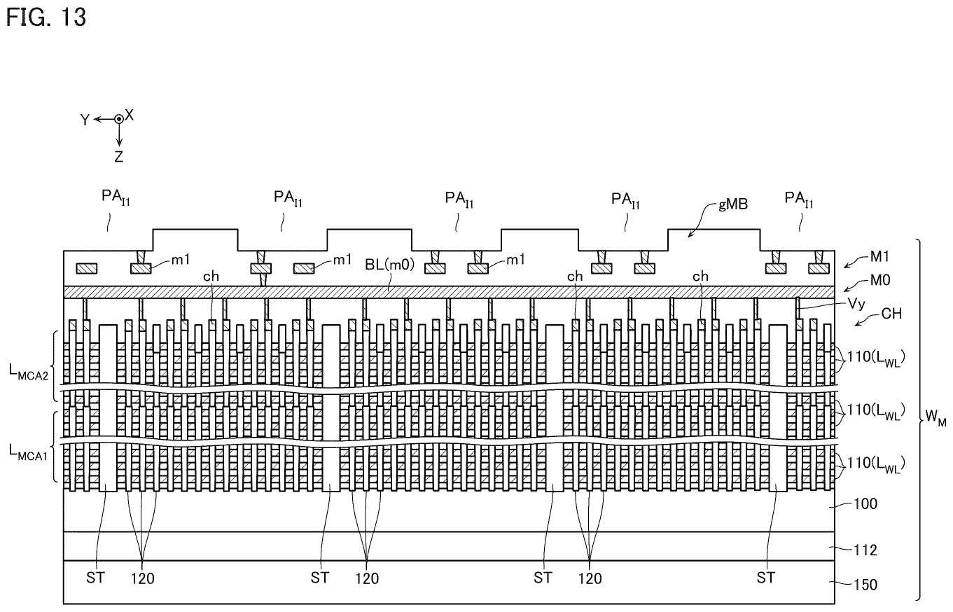

Next, for example, as illustrated in FIG. 13, openings PA_{I1} are formed at positions corresponding to the bonding electrodes P_{I1} (FIG. 5). This process is performed by, for example, a method, such as Reactive Ion Etching (RIE). In this process, for example, the insulating layer gMB at the positions corresponding to the bonding electrodes Pu is removed.

Next, for example, as illustrated in FIG. 14, the bonding electrodes Pu are formed. This process is performed by, for example, forming a conductive layer by sputtering or the like and removing a part of the conductive layer by a method, such as Chemical Mechanical Polishing (CMP).

Although not illustrated, in parallel with the formation of the bonding electrodes P_{I1} described with FIG. 12 to FIG. 14, the bonding electrodes Pₖ₁ₓ are formed in the kerf region R_{K}.

### [Manufacturing Method of Wafer W_{P}]

FIG. 15 illustrates a surface of a semiconductor substrate 250 corresponding to the wafer W_{P}. FIG. 16 illustrates an enlarged portion in FIG. 15. As illustrated in FIG. 15, similarly to the surface of the semiconductor substrate 150, a plurality of device regions R_{MD} and structure body regions R_{ST} arranged in the X-direction and the Y-direction, a kerf region R_{K} disposed between these plurality of device regions R_{MD} and structure body regions R_{ST}, a kerf region R_{K}′ disposed in the vicinity of the structure body regions R_{ST}, and a margin region R_{M} are also disposed on a surface of the semiconductor substrate 250.

The device regions R_{MD} in the wafer R_{M} are basically configured similarly to the device regions R_{MD} in the wafer W_{M}. However, the device regions R_{MD} in the wafer W_{P} include a configuration corresponding to the chip C_{P} instead of the configuration corresponding to the chip C_{M}.

The structure body regions R_{ST} in the wafer W_{P} are basically configured similarly to the structure body regions R_{ST} in the wafer W_{M}. However, the structure body regions R_{ST} in the wafer W_{P} include configurations approximately similar to those of the device regions R_{MD} in the wafer W_{P} instead of the device regions R_{MD} in the wafer W_{M}.

The kerf region R_{K} in the wafer W_{P} is configured approximately similarly to the kerf region R_{K} in the wafer W_{M}. For example, as illustrated in FIG. 16, bonding electrodes Pₖ₂ₓ (fourth bonding electrodes) used for bonding the two wafers W_{M}, We are also disposed in the kerf region R_{K} in the wafer W_{P}. These plurality of bonding electrodes Pₖ₂ₓ are electrically unconnected (in a floating state). All of these plurality of bonding electrodes Pₖ₂ₓ are placed at positions that overlap with any of the bonding electrodes Pₖ₁ₓ (FIG. 9) when viewed in the Z-direction after the wafers W_{M}, W_{P} are bonded.

The kerf region R_{K′} in the wafer W_{P} is configured approximately similarly to the kerf region R_{K}′ in the wafer W_{M}. At least parts of the plurality of bonding electrodes Pₖ₂ₓ disposed in the kerf region R_{K}′ in the wafer W_{P} are placed at positions that do not overlap with any of the bonding electrodes Pₖ₁ₓ when viewed in the Z-direction after the wafers W_{M}, W_{P} are bonded.

The margin region Ry in the wafer W_{P} is configured approximately similarly to the margin region Ry in the wafer W_{M}.

Next, patterning of the bonding electrodes P_{I2}, Pₖ₂ₓ used for bonding the wafers W_{M}, W_{P} is described. For example, similarly to the process described with reference to FIG. 10 and FIG. 11, a plurality of lithographic exposure regions R_{EX} are formed on the wafer W_{P} using a mask used for lithographic exposure to perform lithographic exposure, for example, a plurality of times while changing a position in the X-direction and a plurality of times while changing a position in the Y-direction. Then, in the lithographic exposure regions R_{EX}, a plurality of bonding electrode patterns corresponding to the plurality of bonding electrodes P_{I2} are transferred to the device regions R_{MD} and the structure body regions R_{ST}, and bonding electrode patterns corresponding to the plurality of bonding electrodes Pₖ₂ₓ are transferred to the kerf regions R_{K}, R_{K}′. For example, as illustrated in FIG. 15, in the embodiment, an example in which each of the lithographic exposure regions R_{EX} includes four device regions R_{MD} arranged in the X-direction and the Y-direction is described.

For example, as illustrated in FIG. 17 to FIG. 19, the bonding electrodes P_{I2}, Pₖ₂ₓ are formed by the damascene process.

For example, as illustrated in FIG. 17, an insulating layer gDB of silicon oxide (SiO₂) or the like is formed on a surface of the wiring layer D4. This process is performed by, for example, a method, such as CVD.

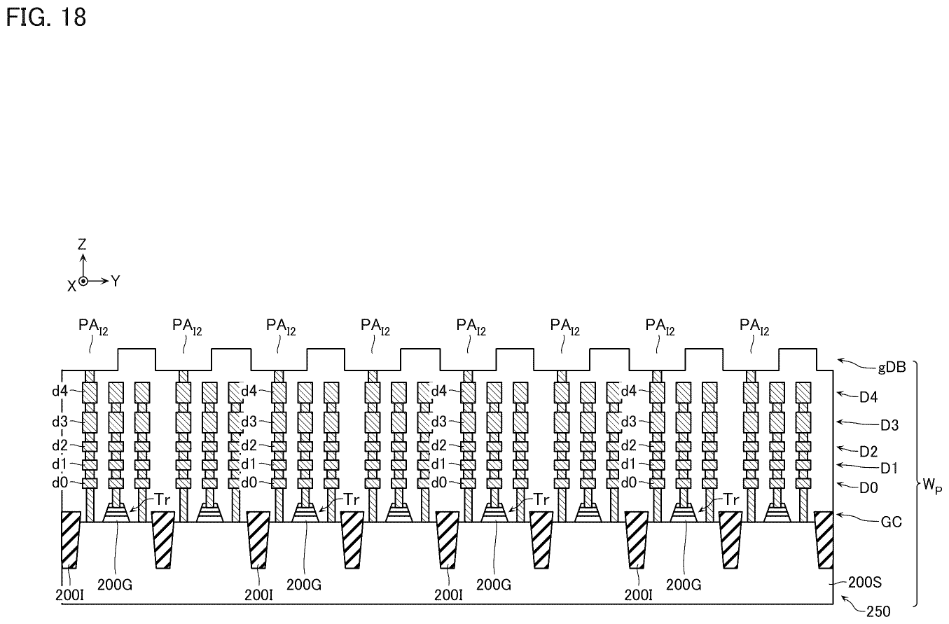

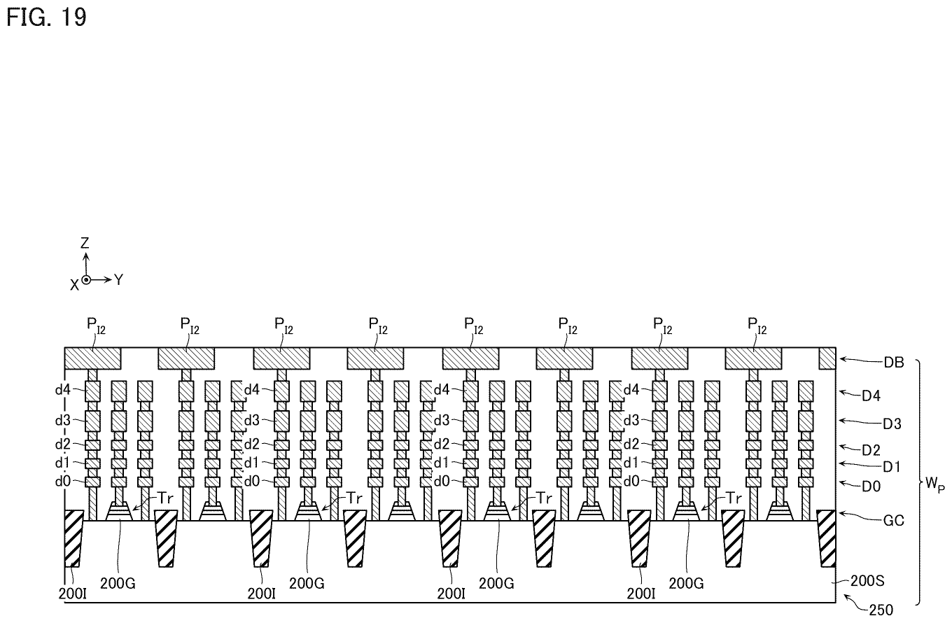

Next, for example, as illustrated in FIG. 18, openings PA_{I2} are formed at positions corresponding to the bonding electrodes P_{I2} (FIG. 5). This process is performed by, for example, a method, such as RIE. In this process, for example, the insulating layer gDB at the positions corresponding to the bonding electrodes P_{I2} is removed. Next, for example, as illustrated in FIG. 19, the bonding electrodes P_{I2} are formed. This process is performed by, for example, forming a conductive layer by sputtering or the like and removing a part of the conductive layer by a method, such as CMP.

Although not illustrated, in parallel with the formation of the bonding electrodes P_{I2} described with FIG. 17 to FIG. 19, the bonding electrodes Pₖ₂ₓ are formed in the kerf region R_{K}.

[Process after Bonding Wafers W_{M}, W_{P}]

After the wafers W_{M}, We are manufactured, as illustrated in FIG. 20, for example, a front surface of the wafer W_{M} and a front surface of the wafer W_{P} are allowed to face one another. In addition, for example, as illustrated in FIG. 21, the wafers W_{M}, W_{P} are bonded. Next, the back side wiring layer MA and the like are formed after the semiconductor substrate 150 and the insulating layer 112 of the wafer W_{M} are removed, and the substrate body structure L_{SB} described with reference to FIG. 5 is formed.

Next, for example, as illustrated in FIG. 22 and FIG. 23, the bonded wafers W_{M}, We are cut along dicing lines DL disposed in the kerf region R_{K} to form a plurality of memory dies MD.

[Bonding Electrodes Pₖ₁ₓ, Pₖ₂ₓ Disposed in Kerf Regions R_{K} of Wafers W_{M}, W_{P}]

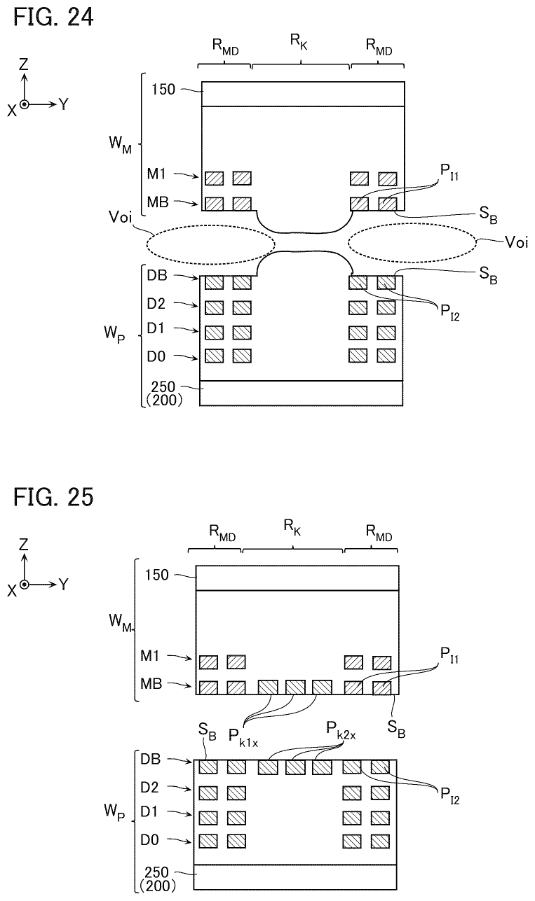

FIG. 24 is a schematic cross-sectional view illustrating structures of the wafers W_{M}, W_{P} in a case where the bonding electrodes Pₖ₁ₓ, Pₖ₂ₓ are not disposed in the kerf regions R_{K}. FIG. 25 is a schematic cross-sectional view illustrating the structures of the wafers W_{M}, W_{P} in a case where the bonding electrodes Pₖ₁ₓ, Pₖ₂ₓ are disposed in the kerf regions R_{K}.

As described above, the wafers W_{M}, W_{P} are formed separately and bonded with respective bonded surfaces SB (front surfaces). For example, in the example of FIG. 24, the bonding electrodes P_{I1}, P_{I2} are disposed in the device regions R_{MD}, and the bonding electrodes Pₖ₁ₓ, Pₖ₂ₓ are not disposed in the kerf regions R_{K}. With such a configuration, on the bonded surfaces SB, level differences may be generated between the device regions R_{MD} and the kerf regions R_{K}. When the level differences are generated, voids Voi are generated between the wafer W_{M} and the wafer W_{P} in a bonding process, increasing the possibility that bonding failures occur.

Therefore, in the embodiment, for example, as illustrated in FIG. 25, the bonded surfaces SB of the wafers W_{M}, We are planarized by disposing the bonding electrodes P_{I1}, P_{I2}, Pₖ₁ₓ, Pₖ₂ₓ in both the device regions R_{MD} and the kerf regions R_{K} to reduce the occurrence of the voids Voi in the bonding process.

[Configuration of Wafers W_{M}, W_{P} after Bonding]

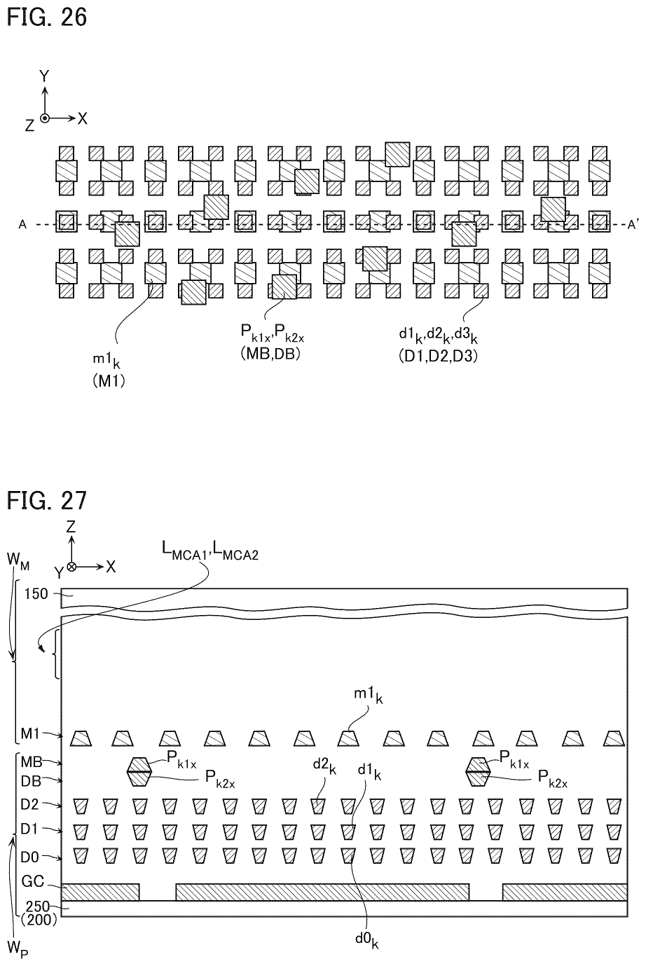

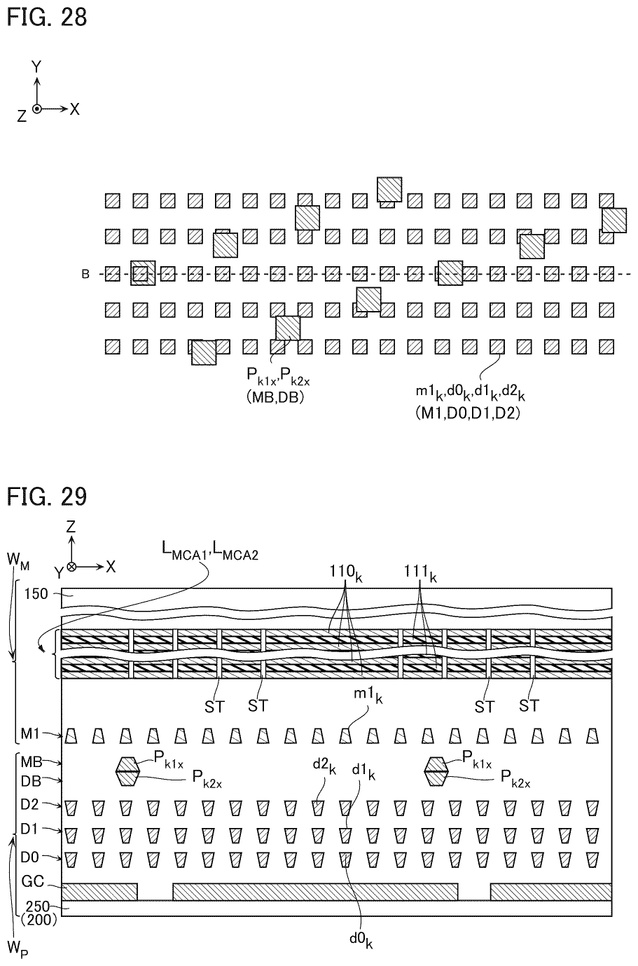

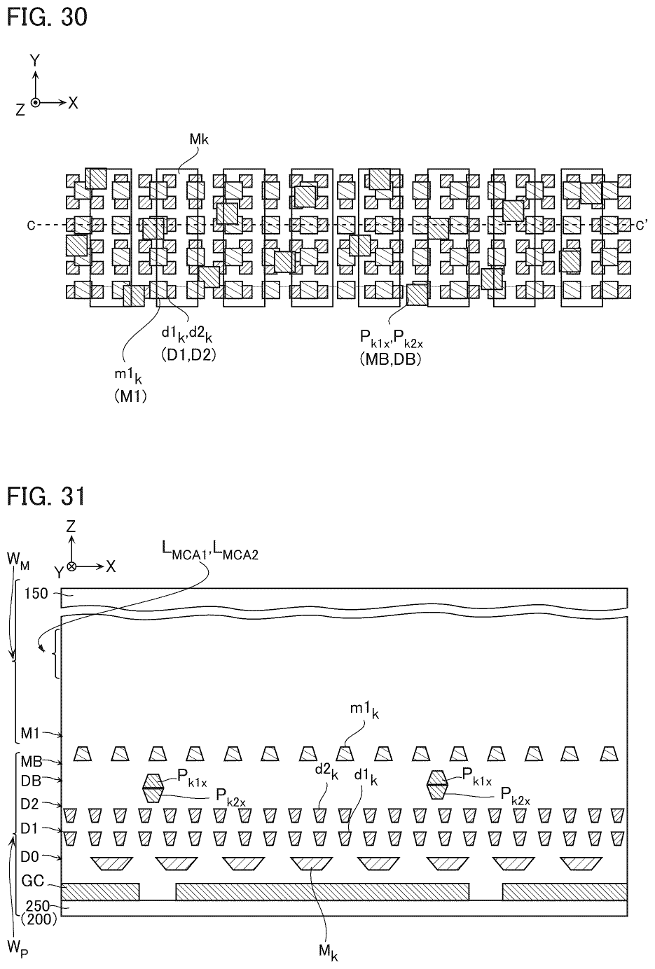

Next, with reference to FIG. 26 to FIG. 31, the configuration of the wafers W_{M}, W_{P} after bonding will be exemplified. FIG. 26, FIG. 28, and FIG. 30 are schematic plan views exemplifying a configuration of a part including kerf regions of the wafers W_{M}, W_{P} after bonding. FIG. 27, FIG. 29, and FIG. 31 are schematic cross-sectional views exemplifying a configuration of a part including the kerf regions of the wafers W_{M}, W_{P} after bonding. FIG. 27 is a view in a case where the configuration illustrated in FIG. 26 is taken along the dotted line A-A′. FIG. 29 is a view in a case where the configuration illustrated in FIG. 28 is taken along the dotted line B-B′. FIG. 31 is a view in a case where the configuration illustrated in FIG. 30 is taken along the dotted line C-C′.

As described above, for example, as illustrated in FIG. 26 and FIG. 27, the bonding electrodes Pₖ₁ₓ, Pₖ₂ₓ disposed on the wiring layers MB, DB in the kerf regions R_{K} are disposed at the positions where they overlap when viewed in the Z-direction. In the embodiment, wirings m1ₖ, d2ₖ, d1ₖ, d0ₖ formed on the wiring layers M1 and the like, D2, D1, DO, and the like in the kerf regions Rx are formed simultaneously with the wirings m1, d2, d1, d0 formed on the wiring layers M1 and the like, D2, D1, D0, and the like in device regions (device regions R_{MD}). These plurality of wirings m1ₖ, d2ₖ, d1ₖ, d0ₖ are electrically unconnected (in a floating state).

For example, as illustrated in FIG. 27, on parts of the memory cell array layers L_{MCA1}, L_{MCA2} in the kerf region R_{K} of the wafer W_{M}, an insulating layer of silicon oxide (SiO₂) or the like is disposed, and configurations corresponding to the word line layers L_{WL} are not disposed. Then, for example, as illustrated in FIG. 26 and FIG. 27, in the kerf region R_{K}, the wirings m1ₖ of the wiring layer M1 and the wirings d2ₖ, d1ₖ, d0ₖ of the wiring layers D2, D1, DO are disposed at positions such that they are positioned to overlap at a constant cycle when viewed in the Z-direction. In the example illustrated in FIG. 27, in the kerf region R_{K}, the wirings mlx and the wirings d2k, d1ₖ, d0ₖ are disposed at the positions such that the wirings m1ₖ overlap at every other position in the Y-direction while the wirings d2ₖ, d1ₖ, d0ₖ overlap at every three positions in the Y-direction. With such a configuration, in dicing, separation of the wafers W_{M}, W_{P} in the kerf regions R_{K} can be reduced, therefore restraining this separation from progressing to device regions.

In addition, for example, as illustrated in FIG. 29, a plurality of conductive layers 110k arranged in the Z-direction corresponding to the word line layers L_{WL} are disposed on other parts of the memory cell array layers L_{MCA1}, L_{MCA2} in the kerf region R_{K} of the wafer W_{M}. Between the respective adjacent plurality of word line layers L_{WL} arranged in the Z-direction, interlayer insulating layers 111k of silicon oxide (SiO₂) or the like are disposed. The conductive layers 110k may include, for example, a stacked film of a barrier conductive film of titanium nitride (TiN) or the like and a metal film of tungsten (W) or the like. Then, for example, as illustrated in FIG. 28 and FIG. 29, in the kerf region R_{K}, the wirings m1ₖ of the wiring layer M1 and the wirings d2ₖ, d1ₖ, d0ₖ of the wiring layers D2, D1, D0 are disposed at positions where they overlap when viewed in the Z-direction. With such a configuration, in dicing, the separation of the wafers W_{M}, W_{P} can be restrained from progressing to the device regions.

Here, as illustrated in FIG. 29, a region where the plurality of conductive layers 110k and the plurality of interlayer insulating layers 111k are formed is hard, compared with a region where the plurality of conductive layers 110k and the plurality of interlayer insulating layers 111k are not formed as illustrated in FIG. 27, and may be difficult to preferably dice. In view of this, in the embodiment, coverage factors on the wiring layers M1, D2, D1, D0 in the region described with reference to FIG. 29 are set to be smaller than coverage factors on the wiring layers M1, D2, D1, D0 in the region described with reference to FIG. 27. Accordingly, similarly to the region described with reference to FIG. 27, dicing can be preferably performed in the region described with reference to FIG. 29.

As illustrated in FIG. 31, an insulating layer of silicon oxide (SiO₂) or the like may be formed in the kerf region R_{K} of the wafer W_{M}, and a region where marks Mₖ are formed may be disposed on the wiring layer D0 in the kerf region R_{K} of the wafer W_{P}. In such a region, the wirings d0ₖ are not formed on the wiring layer D0 in the kerf region Rx. However, the wirings m1ₖ, d2k, d1ₖ are formed on upper layers in the Z-direction of the wiring layer DO, that is, the wiring layers M1, D2, D1, in the kerf region R_{K} of the wafer W_{P}. In addition, the bonding electrodes P_{I1}, P_{I2} are formed on the wiring layers MB, DB. The marks Mₖ formed on the wiring layer DO in the kerf region R_{K} of the wafer W_{P} are used when a layer between the wiring layer D1 and the wiring layer D0 is formed, but not used when layers on and above the wiring layer D1 are formed.

Therefore, even when the wirings m1ₖ and the like are disposed above the marks Mₖ, the memory dies MD are preferably manufacturable. Then, for example, as illustrated in FIG. 30 and FIG. 31, in the kerf region R_{K}, the wirings m1ₖ of the wiring layer M1 and the wirings d2ₖ, d1ₖ of the wiring layers D2, D1 are placed such that they are positioned to overlap at a constant cycle when viewed in the Z-direction.

[Designing Method for Bonding Electrodes Pₖ₁ₓ, Pₖ₂ₓ in Kerf Region R_{K}]

As described with reference to FIG. 24 and FIG. 25, in the embodiment, the bonding electrodes P_{I1}, P_{I2}, Pₖ₁ₓ, Pₖ₂ₓ are disposed in both the device regions R_{MD} and the kerf regions R_{K}. Here, in order to preferably bond the wafers W_{M}, W_{P}, coverage factors of the bonding electrodes P_{I1}, P_{I2}, Pₖ₁ₓ, Pₖ₂ₓ on the bonded surfaces S_{B} (front surfaces) of the wafers W_{M}, W_{P} (proportions of areas of the bonding electrodes P_{I1}, P_{I2}, Pₖ₁ₓ, Pₖ₂ₓ per unit area on the bonded surfaces S_{B}) are preferably large. However, as described later in detail, due to various circumstances, regions where the bonding electrodes Pₖ₁ₓ, Pₖ₂ₓ cannot be placed (hereinafter referred to as “unplaceable regions”) exist in the respective kerf regions Rx of the wafers W_{M}, W_{P}. In addition, the bonding electrodes Pₖ₁ₓ and the bonding electrodes Pₖ₂ₓ are preferably disposed at positions where they overlap when viewed in the Z-direction. This is because when one of the bonding electrode Pₖ₁ₓ and the bonding electrode Pₖ₂ₓ is disposed at a position that does not overlap with the other, there is a risk that metallic atoms in copper (Cu) or the like in the bonding electrodes Pₖ₁ₓ, Pₖ₂ₓ are diffused. Therefore, as many bonding electrodes Pₖ₁ₓ, Pₖ₂ₓ as possible are preferably placed in the kerf regions Rx such that the bonding electrodes Pₖ₁ₓ and the bonding electrodes Pₖ₂ₓ can be disposed at the positions where they overlap when viewed in the Z-direction while avoiding the respective unplaceable regions in the wafers W_{M}, W_{P}.

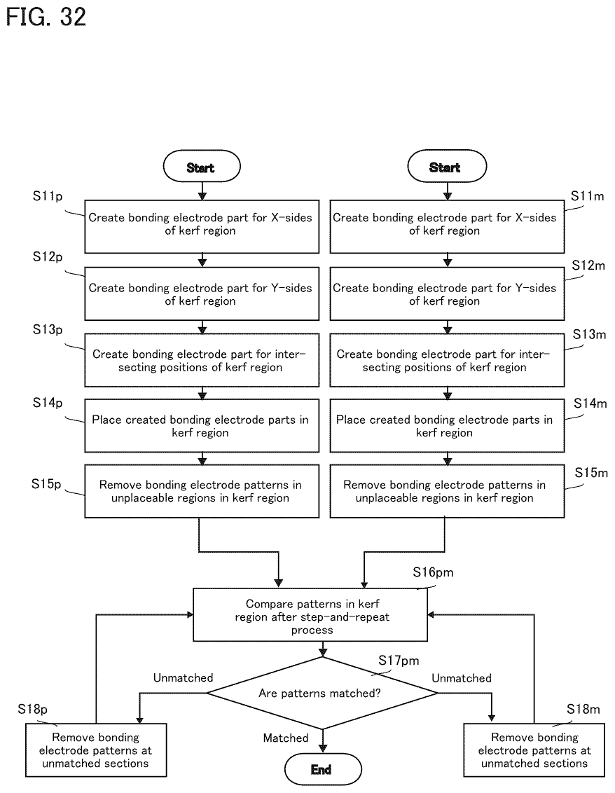

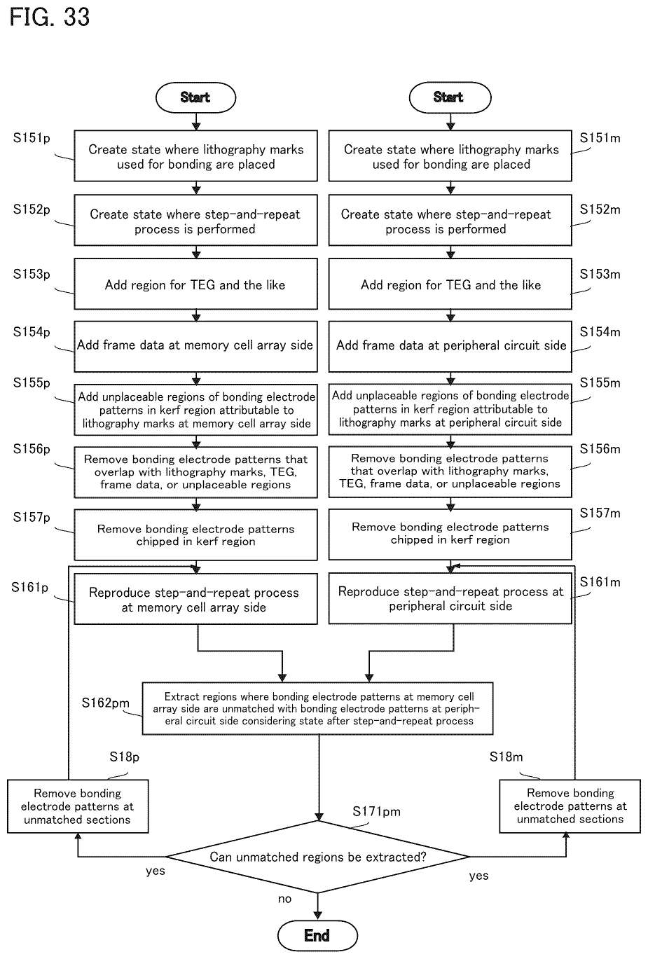

A designing method for masks used for manufacturing the bonding electrodes Pₖ₁ₓ, Pₖ₂ₓ in the kerf regions R_{K} according to the embodiment is described below using FIG. 32 to FIG. 62. FIG. 32 is a flowchart illustrating a processing procedure of design processing for mask data used for manufacturing the bonding electrodes Pₖ₁ₓ, Pₖ₂ₓ in the kerf regions Rx. FIG. 33 is a flowchart illustrating an example of a specific processing procedure of Steps S15p, S15m, and S16pm in FIG. 32. These processing procedures may be performed, for example, with a computer including a memory and a processor (microprocessor) by executing a control program stored in the memory by the processor or may be performed by providing an instruction to the computer by an operator.

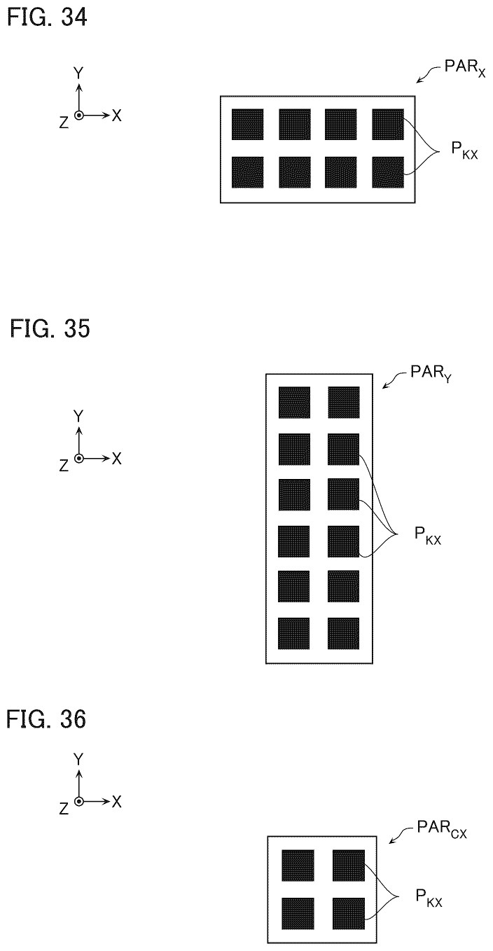

FIG. 34 to FIG. 36 are plan views illustrating exemplary bonding electrode parts for a kerf region. FIG. 34 is a plan view illustrating an example of a bonding electrode part PAR_{X} for X-sides of the kerf region, FIG. 35 is a plan view illustrating an example of a bonding electrode part PAR_{Y} for Y-sides of the kerf region, and FIG. 36 is a plan view illustrating an example of a bonding electrode part PAR_{CX} for intersecting positions of the kerf region.

For example, as illustrated in FIG. 32, first, in Steps S11p to S13p, the bonding electrode part PAR_{X} for the X-sides (FIG. 34), the bonding electrode part PAR_{Y} for the Y-sides (FIG. 35), and the bonding electrode part PAR_{CX} for the intersecting positions (FIG. 36) of the kerf region in the mask data used for manufacturing the wafer W_{P} are created. As illustrated in FIG. 34 to FIG. 36, each of the bonding electrode parts PAR_{X}, PAR_{Y}, PAR_{CX} includes a plurality of bonding electrode patterns P_{KX} (second bonding electrode patterns) corresponding to the plurality of bonding electrodes Pₖ₂ₓ (second bonding electrodes). In Steps S11p to S13p, for example, sizes and shapes of these plurality of bonding electrode patterns P_{KX}, and positions in the X-direction and the Y-direction of the bonding electrode patterns P_{KX} in each of the bonding electrode parts PAR_{X}, PAR_{y}, PAR_{CX} are specified. Note that the order of Steps S11p to S13p is an example and interchangeable as appropriate. In addition, without creating the bonding electrode parts PAR_{X}, PAR_{Y}, PAR_{CX} for the X-sides, the Y-sides, and the intersecting positions, the sizes, shapes, and pitches of the bonding electrode patterns P_{KX} at the X-sides, the Y-sides, and the intersecting positions may be specified.

In Steps S11m to S13m, the bonding electrode part PAR_{X} for the X-sides (FIG. 34), the bonding electrode part PAR_{y} for the Y-sides (FIG. 35), and the bonding electrode part PAR_{CX} for the intersecting positions (FIG. 36) of the kerf region in the mask data used for manufacturing the wafer W_{M} are created. Each of these bonding electrode parts PAR_{X}, PAR_{Y}, PAR_{CX} includes a plurality of bonding electrode patterns P_{KX} (first bonding electrode patterns) corresponding to the plurality of bonding electrodes Pₖ₁ₓ (first bonding electrodes). In Steps S11m to S13m, for example, sizes and shapes of these plurality of bonding electrode patterns P_{KX}, and positions in the X-direction and the Y-direction of the bonding electrode patterns P_{KX} in each of the bonding electrode parts PAR_{X}, PAR_{Y}, PAR_{CX} are specified. Note that the order of Steps S11m to S13m is an example and interchangeable as appropriate. In addition, as described above, without creating the bonding electrode parts PAR_{X}, PAR_{Y}, PAR_{CX} for the X-sides, the Y-sides, and the intersecting positions, the sizes, shapes, and pitches of the bonding electrode patterns P_{KX} at the X-sides, the Y-sides, and the intersecting positions may be specified.

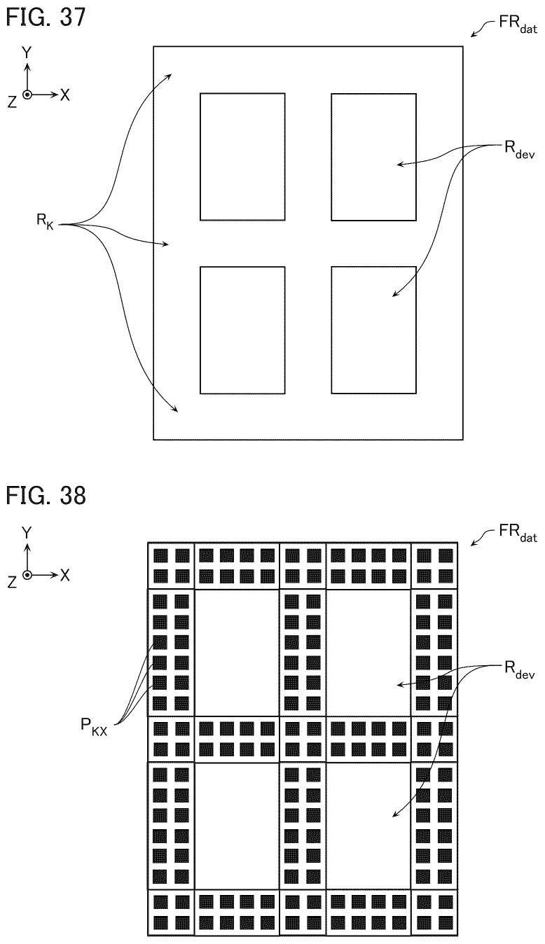

FIG. 37 is a plan view illustrating an example of frame data FR_{dat} of the masks used for manufacturing the bonding electrodes Pₖ₁ₓ, Pₖ₂ₓ in the kerf regions R_{K}. FIG. 38 is a plan view illustrating a state where bonding electrode parts PAR_{X} for the X-sides, bonding electrode parts PAR_{y} for the Y-sides, and bonding electrode parts PAR_{CX} for the intersecting positions are laid on the frame data FR_{dat} illustrated in FIG. 37. In FIG. 37 and FIG. 38, rectangular device regions R_{dev} and the kerf region R_{K} surrounding the device regions R_{dev} are illustrated. The device regions R_{dev} are regions corresponding to the device regions R_{MD} in which the respective chips C_{P}, C_{M} are formed.

Next, in Step S14p, the bonding electrode parts PAR_{X}, PAR_{Y}, PAR_{CX} created in Steps S11p to S13p are placed in the kerf region R. In addition, in Step S14m, the bonding electrode parts PAR_{X}, PAR_{Y}, PAR_{CX} created in Steps S11m to S13m are placed in the kerf region R_{K}.

More specifically, the bonding electrode parts PAR_{X}, PAR_{Y}, PAR_{CX} created in Steps S11p to S13p and Steps S11m to S13m are placed in the kerf region Rx of the frame data FR_{dat} illustrated in FIG. 37. Accordingly, as illustrated in FIG. 38, the bonding electrode patterns P_{KX} are laid on the kerf region R_{K} of the frame data FR_{dat}.

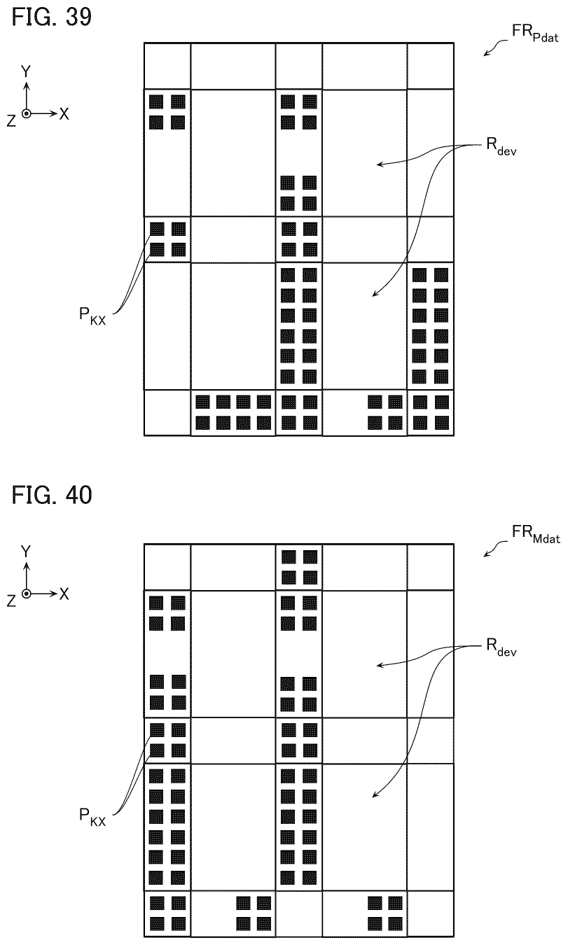

FIG. 39 is a plan view illustrating an example of frame data FR_{Pdat} of the mask used for manufacturing the bonding electrodes Pₖ₂ₓ in the kerf region R_{K} of the wafer W_{P}. FIG. 40 is a plan view illustrating an example of frame data FR_{Mdat} of the mask used for manufacturing the bonding electrodes Pₖ₁ₓ in the kerf region R_{K} of the wafer W_{M}

Next, in Step S15p, bonding electrode patterns P_{KX} in unplaceable regions in the kerf region Rx are removed from the bonding electrode patterns P_{KX} included in the bonding electrode parts PAR_{X}, PAR_{Y}, PAR_{CX} placed in Step S14p. In Step S15p, the unplaceable regions in the kerf region Rx of the frame data FR_{Pdat} of the wafer W_{P} are identified, and the bonding electrode patterns P_{KX} placed in the unplaceable regions are removed from frame data FR_{Pdat} on which the bonding electrode patterns P_{KX} are laid as illustrated in FIG. 38. Accordingly, the frame data FR_{Pdat} on which the bonding electrode patterns P_{KX} are placed as illustrated in FIG. 39 can be obtained.

Here, the unplaceable region in the kerf region Rx is a region where bonding electrode patterns are unplaceable in the kerf region R_{K}. This unplaceable region is a region where, for example, lithography marks, frame data, and test element group (TEG) used after bonding the wafers W_{M}, W_{P} are formed. Lengths in the X-direction and the Y-direction of these regions are greater than respective lengths in the X-direction and the Y-direction of the bonding electrode patterns. The lithography marks are alignment marks used for positioning wiring and openings formed after bonding the wafers W_{M}, W_{P}, detection marks for measuring an overlay accuracy, and the like.

In addition, in Step S15m, bonding electrode patterns P_{KX} in unplaceable regions in the kerf region Rx are removed from the bonding electrode patterns P_{KX} included in the bonding electrode parts PAR_{X}, PAR_{Y}, PAR_{CX} placed in Step S14m. In Step S15m, the unplaceable regions in the kerf region R_{K} of the frame data FR_{Mdat} of the wafer W_{M} are identified, and the bonding electrode patterns P_{KX} placed in the unplaceable regions are removed from the frame data FR_{Mdat} on which the bonding electrode patterns P_{KX} are laid as illustrated in FIG. 38. Accordingly, the frame data FR_{Mdat} on which the bonding electrode patterns P_{X} are placed as illustrated in FIG. 40 can be obtained.

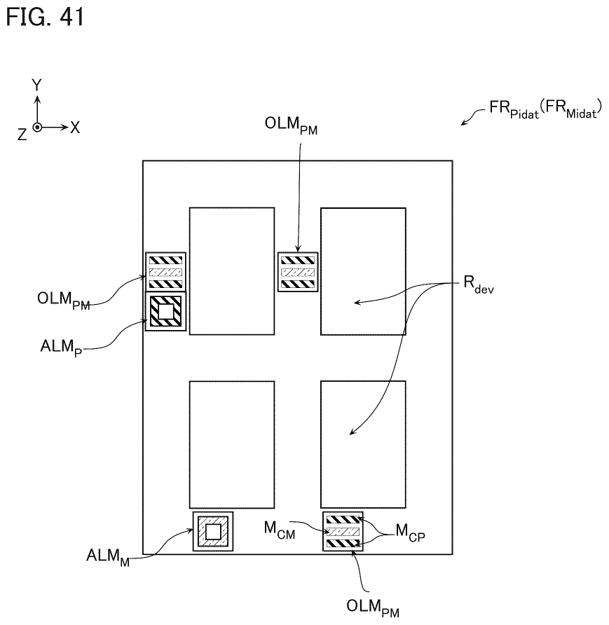

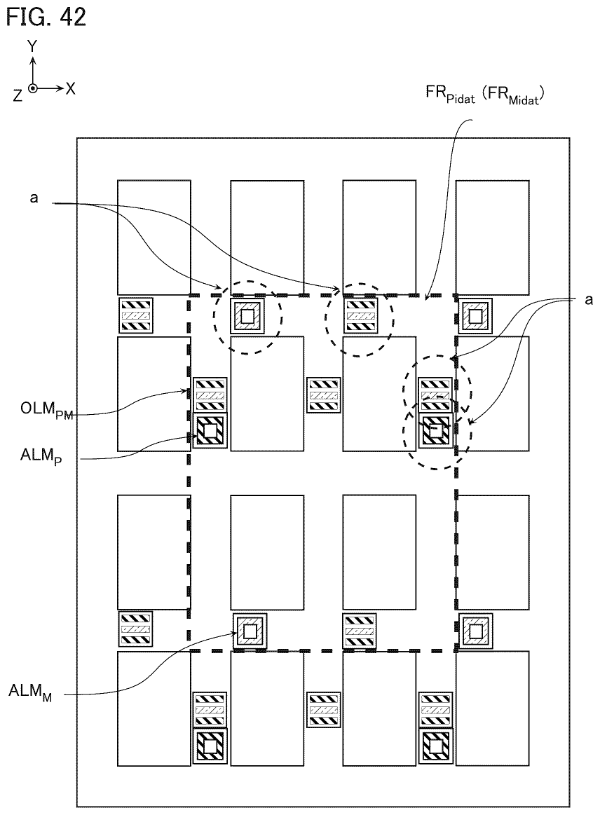

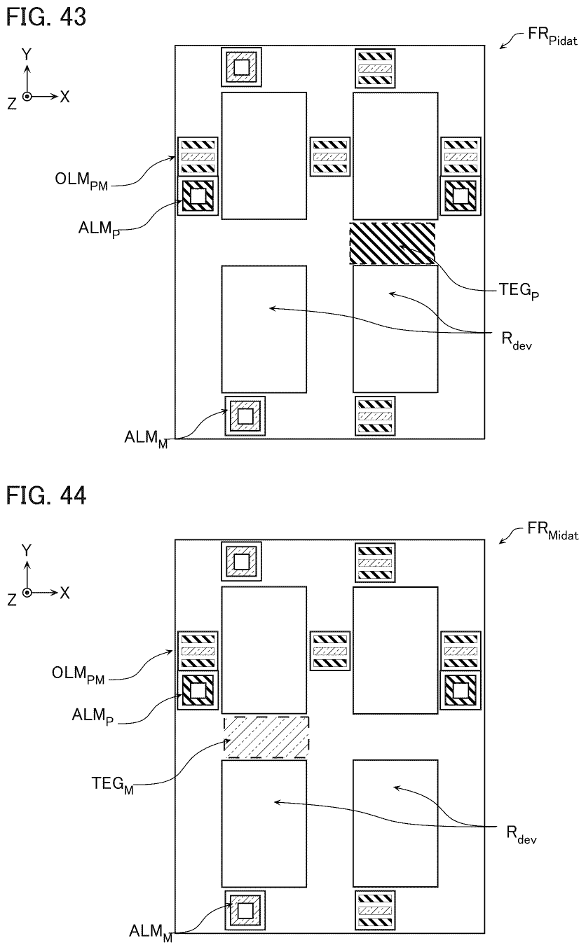

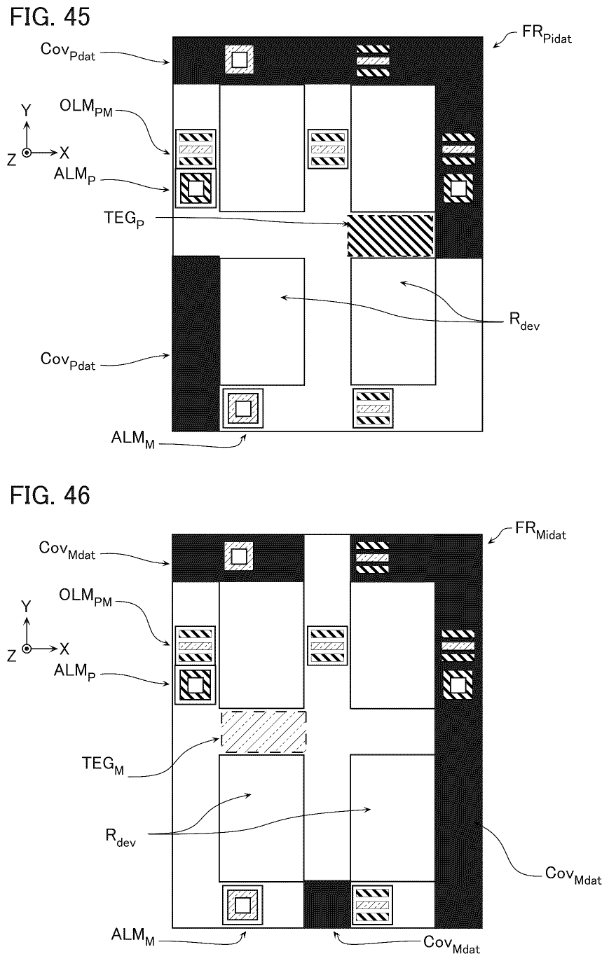

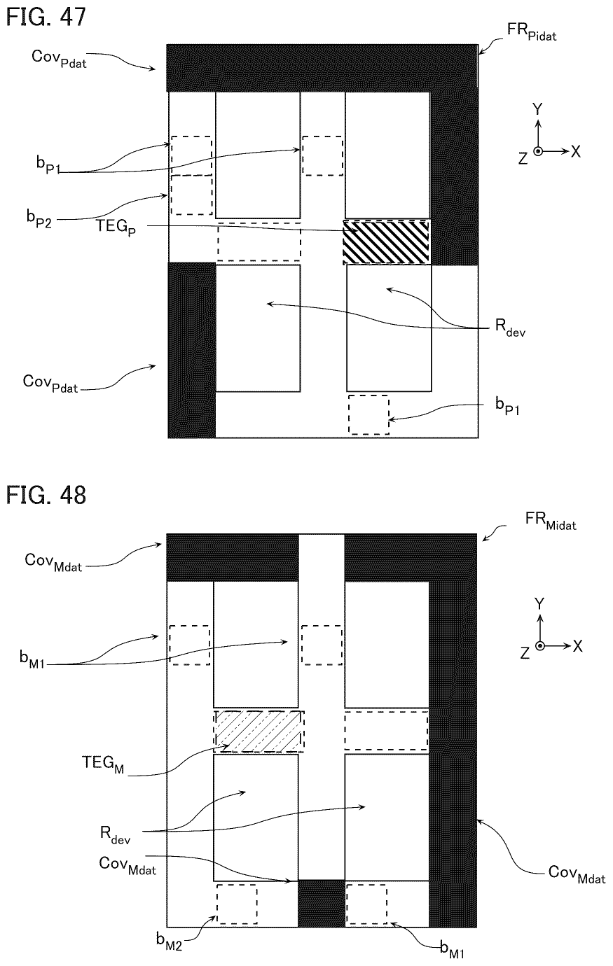

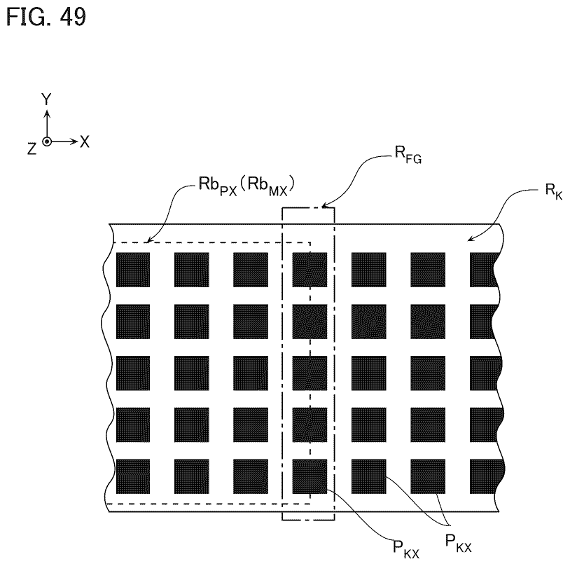

Here, an example of the specific processing procedure of Step S15p and Step S15m is described using FIG. 33 and FIG. 41 to FIG. 49. FIG. 41 is a plan view illustrating an example of frame data FR_{Pidat} (FR_{Midat}) on which lithography marks used for bonding are placed. FIG. 42 is a plan view illustrating exemplary placement of the lithography marks in a state where the frame data FR_{Pidat} (FR_{Midat}) in FIG. 41 is subjected to a step-and-repeat process. FIG. 43 is a plan view illustrating an example of the frame data FR_{Pidat} in a state where a region for TEG and the like is added to the frame data FR_{Pidat} in FIG. 42. FIG. 44 is a plan view illustrating an example of the frame data FR_{Midat} in a state where a region for TEG and the like is added to the frame data FR_{Midat} in FIG. 42. FIG. 45 is a plan view illustrating an example of the frame data FR_{Pidat} in a state where a region for frame data is added to the frame data FR_{Pidat} in FIG. 43. FIG. 46 is a plan view illustrating an example of the frame data FR_{Midat} in a state where a region for frame data is added to the frame data FR_{Midat} in FIG. 44. FIG. 47 is a plan view illustrating unplaceable regions b_{P1}, b_{P2} attributable to lithography marks in the frame data FR_{Pidat}. FIG. 48 is a plan view illustrating unplaceable regions b_{M1}, b_{M2} attributable to lithography marks in the frame data FR_{Midat}. FIG. 49 is a plan view for describing bonding electrode patterns P_{KX} that are chipped due to a placement prohibited region Rb_{PX} (Rb_{MX}) including lithography marks, TEG regions, frame data, or unplaceable regions.

In Step S151p and Step S151m, first, states where the lithography marks used for bonding are placed are created. For example, as illustrated in FIG. 41, the frame data FR_{Pidat}, FR_{Midat} in a state where an alignment mark ALM_{P}, an alignment mark ALM_{M}, and overlay marks OLM_{PM} are placed in the frame data FR_{dat} illustrated in FIG. 37 are created. The alignment mark ALM_{P} is formed in the frame data FR_{Pdat}. The alignment mark ALM_{M} is formed in the frame data FR_{Mdat}. The overlay mark OLM_{PM} illustrated in FIG. 41 is composed of overlay marks M_{CP}, M_{CM}, and while the overlay mark M_{CP} is formed in the frame data FR_{Pdat}, the overlay mark Mom is formed in the frame data FR_{Mdat}.

Next, in Step S152p and Step S152m, states where the step-and-repeat process is performed are created. The state where the step-and-repeat process is performed is created by creating a state where, for example, a mask created from the frame data FR_{Pidat} (FR_{Midat}) in FIG. 41 is used to perform lithographic exposure three times or more while changing a position in the X-direction and three times or more while changing a position in the Y-direction. In the example of FIG. 42, a state where the lithographic exposure is performed three times while changing the position in the X-direction and three times while changing the position in the Y-direction is created. In this case, as illustrated in FIG. 42, lithography marks formed by performing the step-and-repeat process are placed in regions a of the frame data FR_{Pidat} (FR_{Midat}).

Next, in Step S153p and Step S153m, the regions for TEG and the like are added. For example, as illustrated in FIG. 43, the frame data FR_{Pidat} in a state where a region for TEG and the like TEG_{P} is placed in the frame data FR_{Pidat} illustrated in FIG. 42 is created. In addition, for example, as illustrated in FIG. 44, the frame data FR_{Midat} in a state where a region for TEG and the like TEG_{M} is placed in the frame data FR_{Midat} illustrated in FIG. 42, is created. The region for TEG and the like TEG_{P} is formed in the frame data FR_{Pidat}, and the region for TEG and the like TEG_{M} is formed in the frame data FR_{Midat}.

Next, in Step S154p, a region for frame data (light-shielding region pattern) is added to the frame data FR_{Pidat} illustrated in FIG. 43. For example, as illustrated in FIG. 45, the frame data FR_{Pidat} in a state where a frame data region COV_{Pdat} is placed in the frame data FR_{Pidat} illustrated in FIG. 43 is created.

Here, the frame data specifies a light-shielding region for avoiding the bonding electrode patterns and other patterns being doubly transferred by exposure to light at end portions of the lithographic exposure regions R_{EX} (see FIG. 8). The frame data has a pattern that allows all the regions to be exposed to light once and does not allow any regions to be exposed to light twice when the lithographic exposure is performed three times or more while changing a position in the X-direction of a mask and three times or more while changing a position in the Y-direction.

For example, in the frame data FR_{Pidat} in FIG. 45, a region of a part of the kerf region Rx disposed at one end portion in the X-direction overlaps with the frame data region Cov_{Pdat}, and a region of another part of the kerf region Rx disposed at the other end portion in the X-direction overlaps with the frame data region Cov_{Pdat}. A shape and an area of a region obtained by combining the region of the part and the region of the another part are the same as a shape and an area of the kerf region R_{K} disposed at the one end portion in the X-direction and the kerf region R_{K} disposed at the other end portion in the X-direction.

In addition, in the frame data FR_{Pidat} in FIG. 45, the entire kerf region Rx disposed at one end portion in the Y-direction overlaps with the frame data region Cov_{Pdat}, and the kerf region Rx disposed at the other end portion in the Y-direction does not overlap with the frame data region Cov_{Pdat}. Note that a shape and an area of the kerf region R_{K} disposed at the one end portion in the Y-direction is the same as a shape and an area of the kerf region Rx disposed at the other end portion in the Y-direction.

Moreover, in the frame data FR_{Pidat} in FIG. 45, three regions among four corner regions overlap with the frame data region Cov_{Pdat}, and the remaining one region does not overlap with the frame data region Cov_{Pdat}. Shapes and areas of these four corner regions are the same.

In addition, in Step S154m, a region for frame data is added to the frame data FR_{Midat} illustrated in FIG. 44. For example, as illustrated in FIG. 46, the frame data FR_{Mdat} in a state where a frame data region Cov_{Pdat} formed in the frame data FR_{Mdat} is placed in the frame data FR_{Mdat} illustrated in FIG. 44 is created. The frame data region Cov_{Pdat} and the frame data region Cov_{Mdat} differ in shape. Therefore, at least a part of the region Cov_{Pdat} is disposed at a position that does not overlap with at least a part of the region Cov_{Mdat}. Similarly, at least the part of the region Cov_{Mdat} is disposed at a position that does not overlap with at least the part of the region Cov_{Pdat}.

Next, in Step S155p, unplaceable regions of the bonding electrode patterns attributable to lithography marks are identified in the kerf region Rx of the frame data FR_{Pidat}. For example, as illustrated in FIG. 47, in the frame data FR_{Pidat}, unplaceable regions b_{P1}, b_{P2} attributable to lithography marks are identified. The unplaceable regions b_{P1} are regions where the overlay marks OLM_{PM} have been placed. The unplaceable region b_{P2} is a region where the alignment mark ALM_{P} has been placed.

In addition, in Step S155m, unplaceable regions of the bonding electrode patterns attributable to lithography marks are identified in the kerf region Rx of the frame data FR_{Midat}. For example, as illustrated in FIG. 48, in the frame data FR_{Midat}, unplaceable regions b_{M1}, b_{M2} attributable to lithography marks are identified. The unplaceable regions b_{M1} are regions where the overlay marks OLM_{PM} have been placed. The unplaceable region b_{M2} is a region where the alignment mark ALM_{M} has been placed.

Next, in Step S156p, bonding electrode patterns P_{KX} that overlap with the unplaceable regions, that is, bonding electrode patterns P_{KX} that overlap with the lithography marks, TEG regions, frame data, and unplaceable regions, are removed from the bonding electrode patterns P_{KX} in the kerf region Rx of the frame data FR_{Pdat}. In subsequent Step S157p, bonding electrode patterns P_{KX} that are chipped in the kerf region Rx of the frame data FR_{Pdat} are removed.

Here, using FIG. 49, the chipped bonding electrode patterns P_{KX} is described. A placement prohibited region Rb_{PX} (Rb_{MX}) is a region where the bonding electrode patterns P_{KX} cannot be placed in the frame data FR_{Pidat} (FR_{Midat}), and includes, for example, lithography marks, TEG regions, frame data, or unplaceable regions. In the frame data FR_{Pidat}, for example, as illustrated in FIG. 49, only parts of the bonding electrode patterns Pix in a region R_{FG} overlap with the placement prohibited region Rb_{PX} in some cases. In this case, when the bonding electrode patterns P_{KX} that overlap with the placement prohibited region Rb_{PX} are removed from the bonding electrode patterns P_{KX} in the kerf region R_{K}, those with the parts of the bonding electrode patterns P_{KX} in the region R_{FG} chipped, that is, chipped bonding electrode patterns P_{KX} is formed. Therefore, in Step S157p, the bonding electrode patterns P_{KX} that are chipped in the kerf region R_{K} of the frame data FR_{Pdat} are removed.

Thus, as illustrated in FIG. 39, the frame data FR_{Pdat} in which the bonding electrode patterns P_{KX} placed in the unplaceable regions are removed from the frame data FR_{Pdat} on which the bonding electrode patterns P_{KX} are laid as illustrated in FIG. 38 can be obtained.

In addition, in Step S156m, bonding electrode patterns P_{KX} that overlap with the unplaceable regions, that is, bonding electrode patterns P_{KX} that overlap with the lithography marks, TEG regions, frame data, and unplaceable regions, are removed from the bonding electrode patterns P_{KX} in the kerf region R_{K} of the frame data FR_{Midat}. In subsequent Step S157m, bonding electrode patterns P_{KX} that are chipped in the kerf region R_{K} of the frame data FR_{Midat} are removed. In the frame data FR_{Midat}, for example, as illustrated in FIG. 49, only parts of the bonding electrode patterns P_{KX} in the region R_{FG} overlap with the placement prohibited region Rb_{MX} in some cases. In this case, when the bonding electrode patterns P_{KX} that overlap with the placement prohibited region Rb_{MX} are removed from the bonding electrode patterns P_{KX} in the kerf region R_{K}, those with the parts of the bonding electrode patterns P_{KX} in the region R_{FG} chipped, that is, chipped bonding electrode patterns P_{X} is formed. Therefore, in Step S157m, the bonding electrode patterns P_{KX} that are chipped in the kerf region Rx of the frame data FR_{Mdat} are removed.

Thus, as illustrated in FIG. 40, the frame data FR_{Mdat} in which the bonding electrode patterns P_{KX} placed in the unplaceable regions are removed from the frame data FR_{Mdat} on which the bonding electrode patterns P_{KX} are laid as illustrated in FIG. 38 can be obtained.

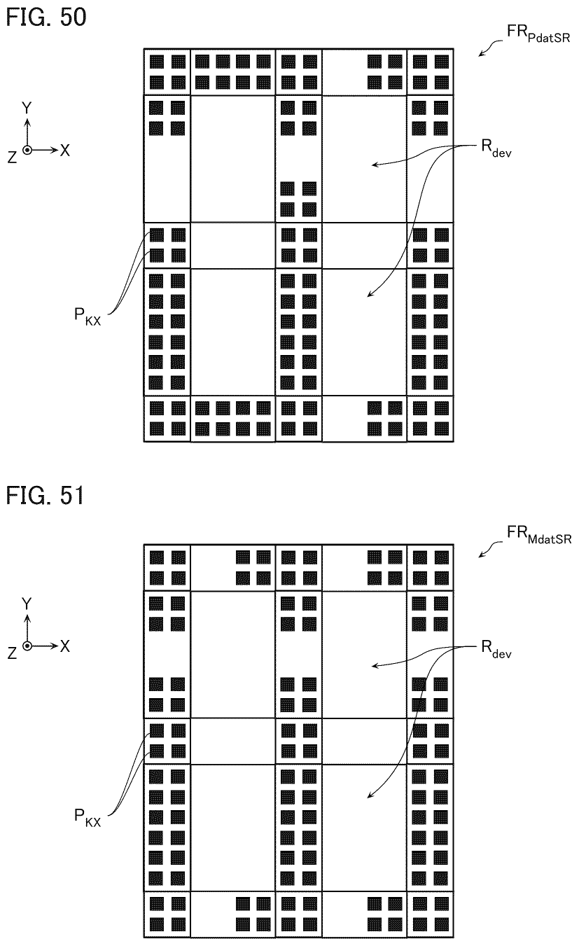

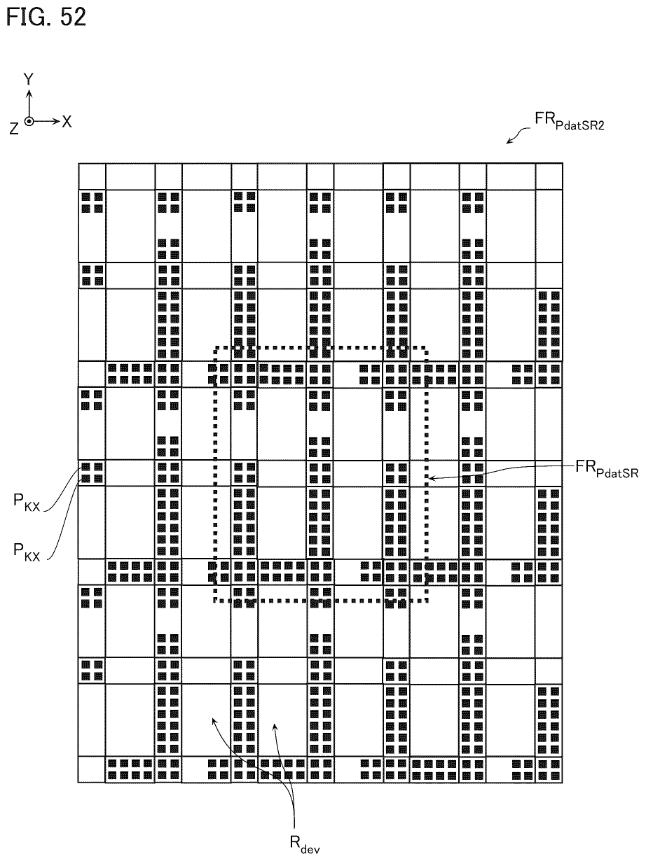

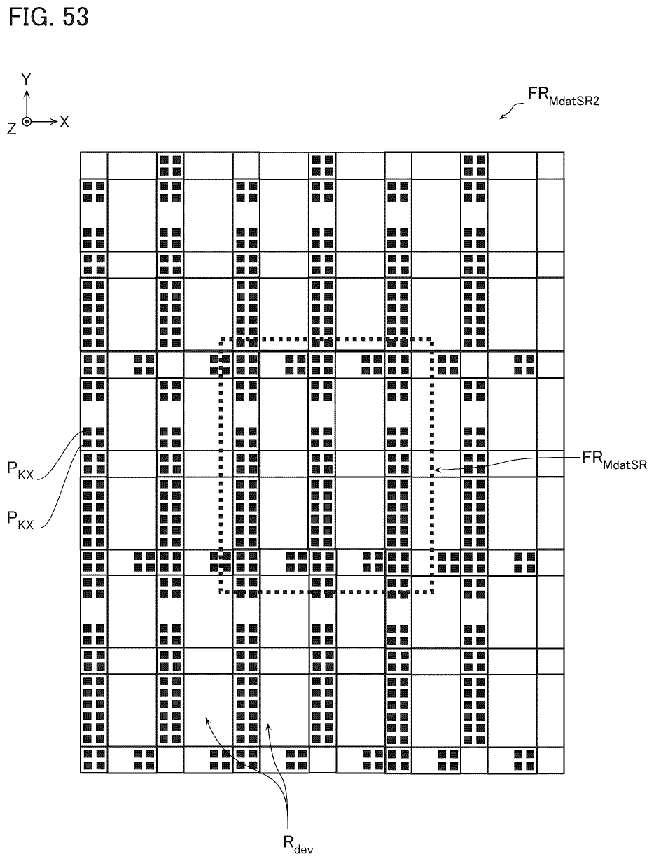

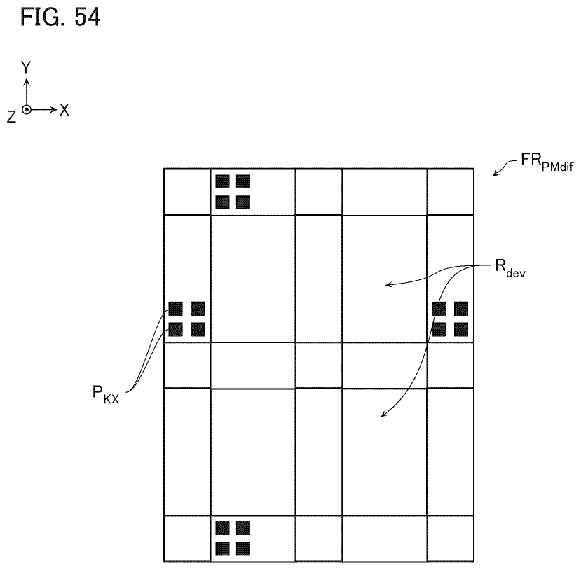

Subsequently, with reference to FIG. 32 and FIG. 33, processing of Step S16pm is described using FIG. 50 to FIG. 54. FIG. 50 is a plan view illustrating frame data FR_{PdatSR} in a state where the frame data FR_{Pdat} in FIG. 39 is subjected to the step-and-repeat process. FIG. 51 is a plan view illustrating frame data FR_{MdatsR} in a state where the frame data FR_{Mdat} in FIG. 40 is subjected to the step-and-repeat process. FIG. 52 is a plan view illustrating an example of reproduction data FR_{PdatSR2} that has reproduced the state where the frame data FR_{Pdat} in FIG. 39 is subjected to the step-and-repeat process. The reproduction data FR_{PdatSR2} in FIG. 52 is data that has reproduced a state where, for example, a mask created from the frame data FR_{Pdat} in FIG. 39 is used to perform lithographic exposure three times while changing a position in the X-direction and three times while changing a position in the Y-direction. FIG. 53 is a plan view illustrating an example of reproduction data FR_{MdatSR2} that has reproduced the state where the frame data FR_{Mdat} in FIG. 40 is subjected to the step-and-repeat process. The reproduction data FR_{MdatSR2} in FIG. 53 is data that has reproduced a state where, for example, a mask created from the frame data FR_{Mdat} in FIG. 40 is used to perform lithographic exposure three times while changing a position in the X-direction and three times while changing a position in the Y-direction. FIG. 54 is a plan view illustrating data FR_{PMaif} that illustrates unmatched sections of the bonding electrode patterns P_{KX} in the kerf region R_{K} after the step-and-repeat process.

Next, in Step S16pm, the bonding electrode patterns in the kerf region Rx after the step-and-repeat process are compared. More specifically, as illustrated in FIG. 33, in Step S161p and Step S161m, the step-and-repeat process at the memory cell array side and the step-and-repeat process at the peripheral circuit side are reproduced.

In Step S161p, as illustrated in FIG. 50, the frame data FR_{PdatSR} on which the bonding electrode patterns P_{KX} are placed is obtained. More specifically, as illustrated by the reproduction data FR_{PdatSR2} in FIG. 52, the frame data FR_{PdatSR} on which the bonding electrode patterns P_{KX} are placed is obtained by reproducing the state where the lithographic exposure is performed with the frame data FR_{Pdat} in FIG. 39 three times while changing the position in the X-direction and three times while changing the position in the Y-direction.

In Step S161m, as illustrated in FIG. 51, the frame data FR_{MdatSR} on which the bonding electrode patterns P_{KX} are placed is obtained. More specifically, as illustrated by the reproduction data FR_{MdatSR2} in FIG. 53, the frame data FR_{MdatSR} on which the bonding electrode patterns P_{KX} are placed is obtained by reproducing the state where the lithographic exposure is performed with the frame data FR_{Mdat} in FIG. 40 three times while changing the position in the X-direction and three times while changing the position in the Y-direction.

Next, as illustrated in FIG. 33, in Step S162pm, considering a state after the step-and-repeat process, a region where the bonding electrode patterns at the memory cell array side are unmatched with the bonding electrode patterns at the peripheral circuit side is extracted. For example, as illustrated in FIG. 54, bonding electrode patterns P_{KX} that are unmatched between the frame data FR_{PdatSR} in FIG. 50 and the frame data FR_{MdatSR} in FIG. 51 are extracted.

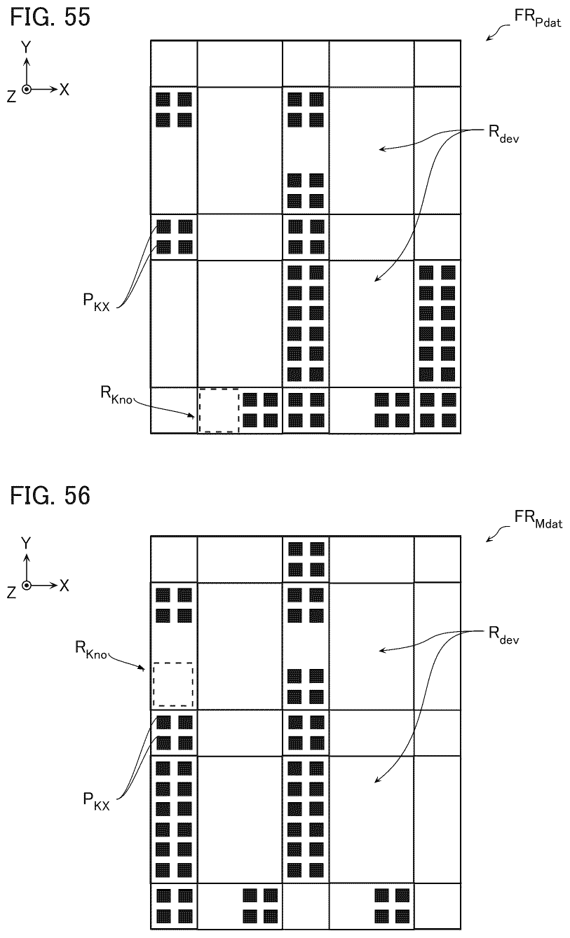

Subsequently, with reference to FIG. 32 and FIG. 33, processing of Steps S17pm, S18p, and S18m is described using FIG. 55 to FIG. 56. FIG. 55 is a plan view illustrating the frame data FR_{Pdat} in which bonding electrode patterns P_{KX} in an unmatched section R_{Kno} are removed from the bonding electrode patterns P_{KX} of the frame data FR_{Pdat} in FIG. 39. FIG. 56 is a plan view illustrating the frame data FR_{Mdat} in which bonding electrode patterns P_{KX} in an unmatched section R_{Kno} are removed from the bonding electrode patterns P_{KX} of the frame data FR_{Mdat} in FIG. 40.

In Step S17pm, as a result of comparing the bonding electrode patterns in the kerf region Rx after the step-and-repeat process, whether the patterns are matched or not is determined. More specifically, in Step S171pm, whether a region where the bonding electrode patterns at the memory cell array side are unmatched with the bonding electrode patterns at the peripheral circuit side can be extracted or not in Step 162pm is determined.

When the bonding electrode patterns in the kerf region R_{K} are matched (matched in Step S17pm), that is, when the region where the bonding electrode patterns at the memory cell array side are unmatched with the bonding electrode patterns at the peripheral circuit side cannot be extracted (no in Step S171pm), the processing ends.

On the other hand, when the bonding electrode patterns in the kerf region R_{K} are determined to be unmatched (unmatched in Step S17pm), that is, when the region where the bonding electrode patterns at the memory cell array side are unmatched with the bonding electrode patterns at the peripheral circuit side can be extracted (yes in Step S171pm), the bonding electrode patterns at unmatched sections are removed in Step S18p and Step S18m.

In Step S18p, as illustrated in FIG. 55, the bonding electrode patterns P_{KX} in the unmatched section R_{Kno} are removed from the bonding electrode patterns P_{KX} placed in the frame data FR_{Pdat} in FIG. 39. Similarly, in Step S18m, as illustrated in FIG. 56, the bonding electrode patterns P_{KX} in the unmatched section R_{Kno} are removed from the bonding electrode patterns P_{KX} placed in the frame data FR_{Mdat} in FIG. 40.

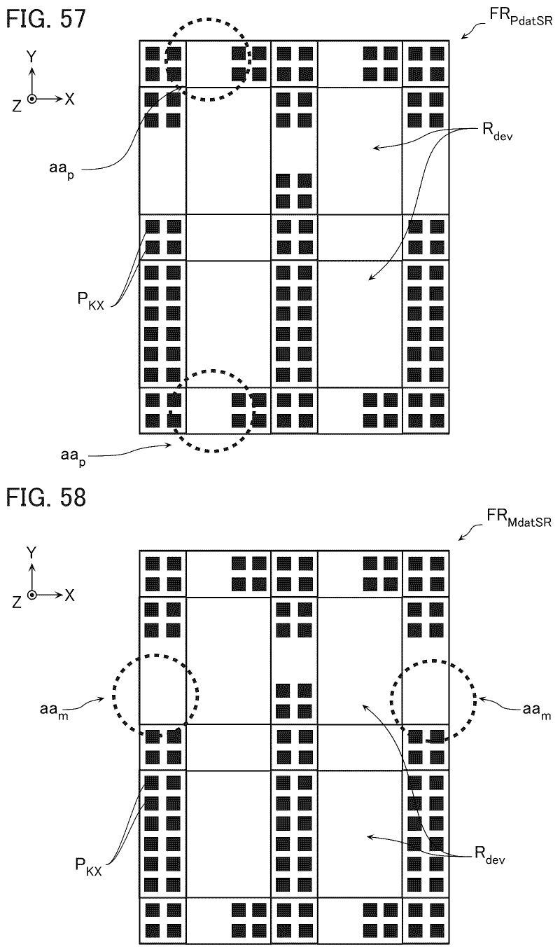

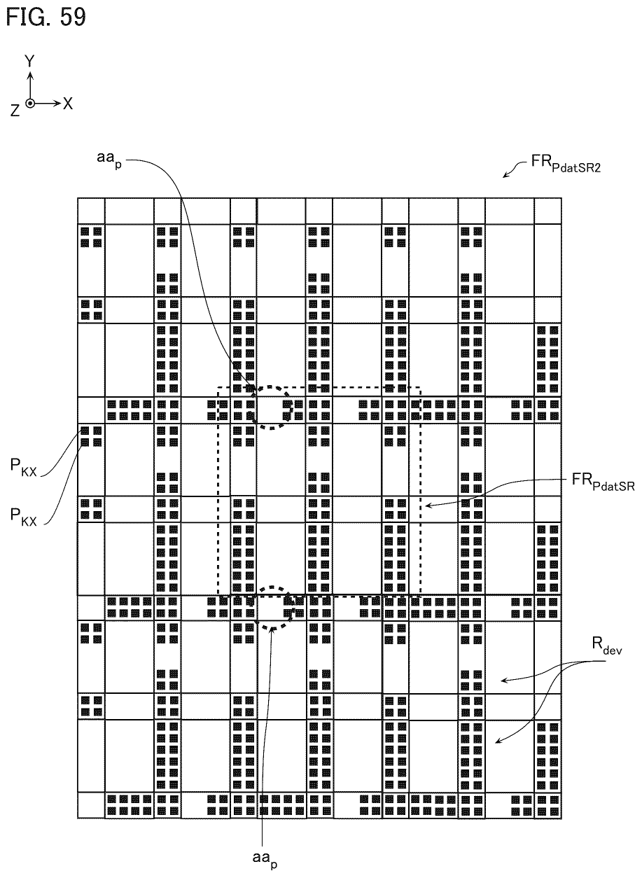

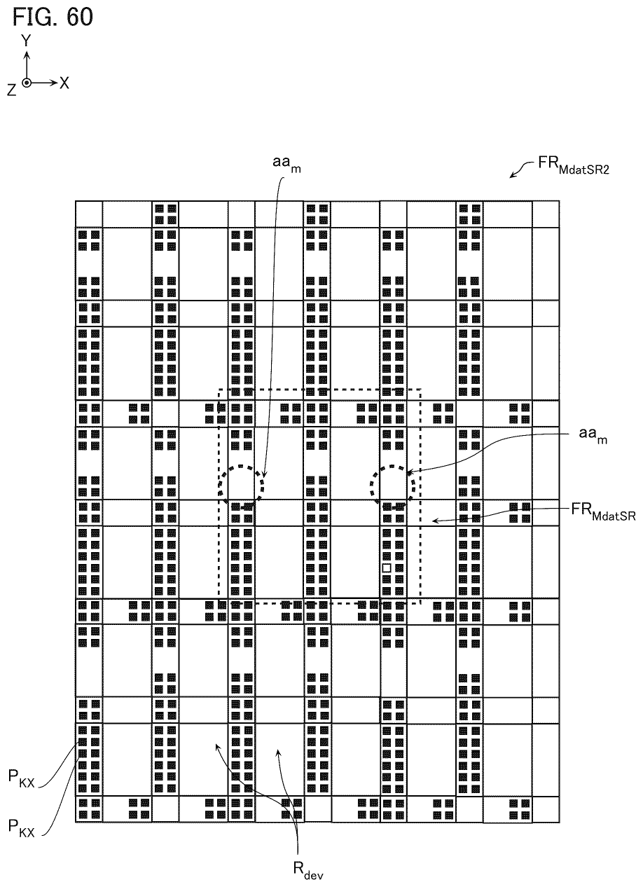

Subsequently, with reference to FIG. 32 and FIG. 33, processing after Steps S18p and S18m is described using FIG. 57 to FIG. 60. FIG. 57 is a plan view illustrating the frame data FR_{PdatsR} in a state where the frame data FR_{Pdat} in FIG. 55 is subjected to the step-and-repeat process. FIG. 58 is a plan view illustrating the frame data FR_{MdatSR} in a state where the frame data FR_{Mdat} in FIG. 56 is subjected to the step-and-repeat process. FIG. 59 is a plan view illustrating an example of the reproduction data FR_{PdatSR2} that has reproduced the state where the frame data FR_{Pdat} in FIG. 55 is subjected to the step-and-repeat process. The reproduction data FR_{PdatSR2} in FIG. 59 is data that has reproduced a state where, for example, a mask created from the frame data FR_{Pdat} in FIG. 55 is used to perform lithographic exposure three times while changing a position in the X-direction and three times while changing a position in the Y-direction. FIG. 60 is a plan view illustrating an example of the reproduction data FR_{MdatSR2} that has reproduced the state where the frame data FR_{Mdat} in FIG. 56 is subjected to the step-and-repeat process. The reproduction data FR_{MdatSR2} in FIG. 60 is data that has reproduced a state where, for example, a mask created from the frame data FR_{Mdat} in FIG. 56 is used to perform lithographic exposure three times while changing a position in the X-direction and three times while changing a position in the Y-direction.

Next, in the second Step S16pm, the bonding electrode patterns in the kerf region R_{K} after the step-and-repeat process are compared. More specifically, as illustrated in FIG. 33, in the second Step S161p and Step S161m, the step-and-repeat process at the memory cell array side and the step-and-repeat process at the peripheral circuit side are reproduced.

In the second Step S161p, as illustrated in FIG. 57, the frame data FR_{PdatSR} on which the bonding electrode patterns P_{KX} are placed is obtained. More specifically, as illustrated by the reproduction data FR_{PdatSR2} in FIG. 59, the frame data FR_{PdatsR} on which the bonding electrode patterns P_{KX} are placed is obtained by reproducing the state where the lithographic exposure is performed with the frame data FR_{Pdat} in FIG. 55 three times while changing the position in the X-direction and three times while changing the position in the Y-direction. Note that regions aaₚ of the frame data FR_{PdatsR} illustrated in FIG. 57 and FIG. 59 indicate sections where the bonding electrode patterns P_{KX} are not reproduced compared to the frame data FR_{PdatSR} in FIG. 50 and FIG. 52 obtained in the first Step S161p.

In the second Step S161m, as illustrated in FIG. 58, the frame data FR_{MdatSR} on which the bonding electrode patterns P_{KX} are placed is obtained. More specifically, as illustrated by the reproduction data FR_{MdatSR2} in FIG. 60, the frame data FR_{MdatSR} on which the bonding electrode patterns P_{KX} are placed is obtained by reproducing the state where the lithographic exposure is performed with the frame data FR_{Mdat} in FIG. 56 three times while changing the position in the X-direction and three times while changing the position in the Y-direction. Note that regions aaₘ of the frame data FR_{MdatSR} illustrated in FIG. 58 and FIG. 60 indicate sections where the bonding electrode patterns P_{KX} are not reproduced compared to the frame data FR_{MdatSR} in FIG. 51 and FIG. 53 obtained in the first Step S161m. Next, as illustrated in FIG. 33, in the second Step S162pm, considering a state after the step-and-repeat process, a region where the bonding electrode patterns at the memory cell array side are unmatched with the bonding electrode patterns at the peripheral circuit side is extracted. For example, as it can be seen by comparing FIG. 57 with FIG. 58, the bonding electrode patterns P_{KX} placed in the frame data FR_{PdatSR} in FIG. 57 are matched with the bonding electrode patterns P_{X} placed in the frame data FR_{MdatSR} in FIG. 58. Therefore, through the next second Step S171pm (Step S17pm), the design processing for the mask data used for manufacturing the bonding electrodes Pₖ₁ₓ, Pₖ₂ₓ in the kerf regions R_{K} ends.

Note that processing after Steps S18p and S18m need not be performed. More specifically, the second Step S161m, Step S161p, Step S162pm, and Step S171pm need not be performed.

### [Masks Used for Patterning Wiring Layers MB, DB]

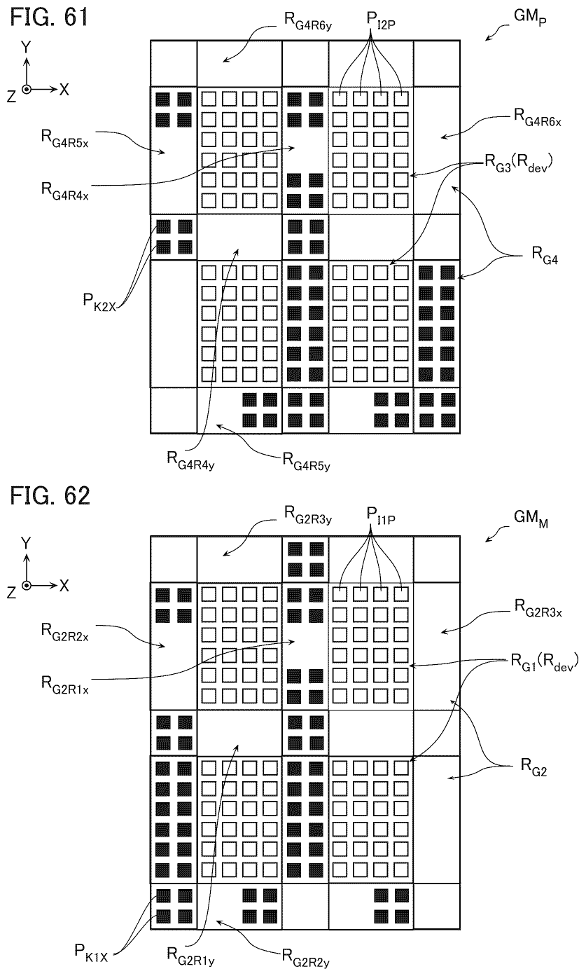

FIG. 62 and FIG. 61 are schematic plan views exemplifying configurations of masks used for patterning the wiring layers MB, DB. FIG. 61 illustrates a mask GM_{P} used for patterning the wiring layer DB in the wafer W_{P}. A third mask region R_{G3} in FIG. 61 is a region corresponding to the device region R_{dev} described above. FIG. 62 illustrates a mask GM_{M} used for patterning the wiring layer MB in the wafer W_{M}. A first mask region Rei in FIG. 62 is a region corresponding to the device region R_{dev} described above.

The masks GM_{M}, GM_{P} illustrated in FIG. 62 and FIG. 61 constitute a mask set used for lithographic exposure in patterning the plurality of bonding electrodes Pu, P_{I2}, Pₖ₁ₓ, Pₖ₂ₓ in the wafers W_{M}, W_{P} that are bonded via the plurality of bonding electrodes Pu, P_{I2}, Pₖ₁ₓ, Pₖ₂ₓ. The masks GM_{M}, GM_{P} are, for example, made of quartz glass, a metal such as chromium (Cr), or the like.

The mask GM_{M} (first mask) illustrated in FIG. 62 includes a plurality of first mask regions R_{G1} disposed at positions corresponding to the plurality of device regions R_{dev} (first device regions) in the wafer W_{M} (first wafer) and including a plurality of first bonding electrode patterns Pup corresponding to parts of the plurality of bonding electrodes P_{I1}, Pₖ₁ₓ (bonding electrodes Pu) and a second mask region R_{G2} disposed at a position corresponding to the kerf region R_{K} surrounding the device regions R_{dev} (first device regions) and including second bonding electrode patterns Pₖ₁ₓ in an electrically unconnected state corresponding to other parts of the plurality of bonding electrodes P_{I1}, Pₖ₁ₓ (bonding electrodes Pₖ₁ₓ).

As illustrated in FIG. 62, this second mask region R_{G2} includes a first region R_{G2R1x}, a second region R_{G2R2x}, and a third region R_{G2R3x}. The first region R_{G2R1x} is disposed between a pair of first mask regions Rai adjacent in the X-direction. The second region R_{G2R2x} is disposed on one side in the X-direction (a positive side in the X-direction in the drawing) with respect to the plurality of device regions R_{dev}. The third region R_{G2R3x} is disposed on the other side in the X-direction (a negative side in the X-direction in the drawing) with respect to the plurality of device regions R_{dev}.

Additionally, as illustrated in FIG. 62, this second mask region R_{G2} includes a first region R_{G2R1y}, a second region R_{G2R2y}, and a third region R_{G2R3y}. The first region R_{G2R1y} is disposed between a pair of first mask regions R_{G1} adjacent in the Y-direction. The second region R_{G2R2y} is disposed on one side in the Y-direction (a positive side in the Y-direction in the drawing) with respect to the plurality of device regions R_{dev}. The third region R_{G2R3y} is disposed on the other side in the Y-direction (a negative side in the Y-direction in the drawing) with respect to the plurality of device regions R_{dev}.

The mask GM_{P} (second mask) illustrated in FIG. 61 includes a plurality of third mask regions R_{G3} disposed at positions corresponding to the plurality of device regions R_{dev} (second device regions) in the wafer W_{P} (second wafer) and including a plurality of third bonding electrode patterns P_{I2P} corresponding to parts of the plurality of bonding electrodes P_{I2}, Pₖ₂ₓ (bonding electrodes P_{I2}) and a fourth mask region R_{G4} disposed at a position corresponding to the kerf region R_{K} surrounding the device regions R_{dev} (second device regions) and including fourth bonding electrode patterns P_{K2X} in an electrically unconnected state corresponding to the others of the plurality of bonding electrodes P_{I2}, Pₖ₂ₓ (bonding electrodes Pₖ₂ₓ).

As illustrated in FIG. 61, this fourth mask region R_{G4} includes a fourth region R_{G4R4x}, a fifth region R_{G4R5x}, and a sixth region R_{G4R6x}. The fourth region R_{G4R4x} is disposed between a pair of third mask regions R_{G3} adjacent in the X-direction. The fifth region R_{G4R5x} is disposed on one side in the X-direction (the positive side in the X-direction in the drawing) with respect to the plurality of device regions R_{dev}. The sixth region R_{G4R6x} is disposed on the other side in the X-direction (the negative side in the X-direction in the drawing) with respect to the plurality of device regions R_{dev}.

Additionally, as illustrated in FIG. 61, this fourth mask region R_{G4} includes a fourth region R_{G4R4y}, a fifth region R_{G4R5y}, and a sixth region R_{G4R6y}. The fourth region R_{G4R4y} is disposed between a pair of third mask regions R_{G3} adjacent in the Y-direction. The fifth region R_{G4R5y} is disposed on one side in the Y-direction (the positive side in the Y-direction in the drawing) with respect to the plurality of device regions R_{dev}. The sixth region R_{G4R6y} is disposed on the other side in the Y-direction (the negative side in the Y-direction in the drawing) with respect to the plurality of device regions R_{dev}.

For the plurality of second bonding electrode patterns Pₖ₁ₓ, a plurality of second bonding electrode patterns Pₖ₁ₓ disposed in the first regions R_{G2R1x}, R_{G2R1y} are disposed at positions that overlap with the plurality of fourth bonding electrode patterns P_{K2X} disposed in the fourth regions R_{G4R4x}, R_{G4R4y}. In addition, for the plurality of second bonding electrode patterns Pₖ₁ₓ, a plurality of second bonding electrode patterns Pₖ₁ₓ in a pattern group obtained by combining the plurality of second bonding electrode patterns Pₖ₁ₓ disposed in the second regions R_{G2R2x}, R_{G2R2y} and the plurality of second bonding electrode patterns Pix disposed in the third regions R_{G2R3x}, R_{G2R3y} are disposed at positions that overlap with any of the plurality of fourth bonding electrode patterns P_{K2X} in a pattern group obtained by combining the plurality of fourth bonding electrode patterns P_{K2X} disposed in the fifth regions R_{G4R5x}, R_{G4R5y} and the plurality of fourth bonding electrode patterns P_{K2X} disposed in the sixth regions R_{G4R6x}, R_{G4R6y}.

Then, in the masks GM_{M}, GM_{P} in FIG. 62 and FIG. 61, at least parts of the plurality of second bonding electrode patterns Pₖ₁ₓ disposed in the second regions R_{G2R2x}, R_{G2R2y} are disposed at positions that do not overlap with any of the plurality of fourth bonding electrode patterns P_{K2X} disposed in the fifth regions R_{G4R5x}, R_{G4R5y}.

In the masks GM_{M}, GM_{P} in FIG. 62 and FIG. 61, frame data different from one another are used.

More specifically, the mask GM_{M} illustrated in FIG. 62 includes a first light-shielding region that is disposed in the second regions R_{G2R2x}, R_{G2R2y}, does not include any of the plurality of second bonding electrode patterns Pₖ₁ₓ, and has lengths in the X-direction and the Y-direction larger than lengths in the X-direction and the Y-direction of the second bonding electrode patterns Pₖ₁ₓ and a second light-shielding region that is disposed in the third regions R_{G2R3x}, R_{G2R3y}, does not include any of the plurality of second bonding electrode patterns Pₖ₁ₓ, and has lengths in the X-direction and the Y-direction larger than the lengths in the X-direction and the Y-direction of the second bonding electrode patterns Pₖ₁ₓ. The first light-shielding region and the second light-shielding region are disposed at positions where they do not overlap.

In addition, the mask GM_{P} illustrated in FIG. 61 includes a third light-shielding region that is disposed in the fifth regions R_{G4R5x}, R_{G4R5y}, does not include any of the plurality of fourth bonding electrode patterns P_{K2x}, and has lengths in the X-direction and the Y-direction larger than lengths in the X-direction and the Y-direction of the fourth bonding electrode patterns P_{K2X} and a fourth light-shielding region that is disposed in the sixth regions R_{G4R6x}, R_{G4R6y}, does not include any of the plurality of fourth bonding electrode patterns P_{K2X}, and has lengths in the X-direction and the Y-direction larger than the lengths in the X-direction and the Y-direction of the fourth bonding electrode patterns P_{K2X}. The third light-shielding region and the fourth light-shielding region are disposed at positions where they do not overlap.

A shape of a pattern group obtained by combining the first light-shielding region and the second light-shielding region is different from a shape of a pattern group obtained by combining the third light-shielding region and the fourth light-shielding region. Note that the shapes of the pattern groups correspond to shapes of the frame data described above.

Typically, a size of a bonding electrode pattern is about several hundred nm to several μm. On the other hand, a size of a frame data pattern is about several dozen μm to several hundred μm in width and about several dozen mm in length. That is, both differ in size by at least one order of magnitude.

[Wafers W_{M}, W_{P} on which Kerf Regions R_{K} of Bonded Surfaces are Formed by Lithographic Exposure]

In manufacturing the wafer W_{M}, the mask GM_{M} illustrated in FIG. 62 is used to perform lithographic exposure a plurality of times while changing the position in the X-direction and a plurality of times while changing the position in the Y-direction as described with reference to FIG. 10 and FIG. 11, thereby forming the wiring layer MB of the bonded surface. Similarly, in manufacturing the wafer W_{P}, the mask GM_{P} illustrated in FIG. 61 is used to perform lithographic exposure a plurality of times while changing the position in the X-direction and a plurality of times while changing the position in the Y-direction, thereby forming the wiring layer MB of the bonded surface. Thus, since the wiring layer MB of the bonded surface is formed in a manner of performing lithographic exposure a plurality of times while changing the respective positions in the X-direction and the Y-direction, positions of at least parts of the bonding electrodes Pₖ₁ₓ in the kerf region R_{K}′ of the wafer W_{M} described with reference to FIG. 8 are not matched with positions of any bonding electrodes Pₖ₂ₓ in the kerf region R_{K}′ of the wafer W_{P} described with reference to FIG. 15. Similarly, positions of at least parts of the bonding electrodes Pₖ₂ₓ in the kerf region R_{K}′ of the wafer W_{P} described with reference to FIG. 15 are not matched with positions of any bonding electrodes Pₖ₁ₓ in the kerf region R_{K′} of the wafer W_{M} described with reference to FIG. 8.

As described with reference to FIG. 10 and FIG. 11, when the mask GM_{M} (GM_{P}) is used to perform lithographic exposure a plurality of times while changing the positions in the X-direction and the Y-direction, there are sections where parts of the lithographic exposure regions R_{EX} protrude from the wafer W_{M} (W_{P}). In the protruding sections, the structure body regions R_{ST} described with reference to FIG. 8 or FIG. 15 are formed.

### [Effect of Embodiment]

With the embodiment, since the occurrence of voids can be reduced even when the wafers W_{M}, W_{P} are bonded with the bonded surfaces S_{B}, a manufacturing yield of a semiconductor device can be improved. This effect is described below.

With the configurations of the wafers W_{M}, W_{P} according to the embodiment, while the frame data having different shapes are formed in the masks GM_{M}, GM_{P} used for manufacturing the bonding electrodes Pₖ₁ₓ, Pₖ₂ₓ in the kerf regions R_{K} of the wafers W_{M}, W_{P}, the bonding electrodes Pₖ₁ₓ, Pₖ₂ₓ are manufactured such that the respective positions of the bonding electrodes Pₖ₁ₓ, Pₖ₂ₓ disposed in the kerf regions Rx overlap with one another at the time of bonding. Accordingly, when the bonded surfaces S_{B} are planarized and the wafers W_{M}, W_{P} are bonded with the bonded surfaces S_{B}, the occurrence of the voids can be reduced in the vicinity of boundaries between the device regions R_{MD} and the kerf regions R_{K}.

With the designing method for the masks GM_{M}, GM_{P} according to the embodiment, even when the frame data having different shapes are formed in the masks GM_{M}, GM_{P} used for manufacturing the bonding electrodes Pₖ₁ₓ, Pₖ₂ₓ in the kerf regions R of the wafers W_{M}, W_{P}, the bonding electrodes Pₖ₁ₓ, Pₖ₂ₓ can be manufactured such that the respective positions of the bonding electrodes Pₖ₁ₓ, Pₖ₂ₓ disposed in the kerf regions Rx overlap and are matched with one another at the time of bonding.

Since alignment marks used after bonding are formed in the masks GM_{M}, GM_{P}, the bonding electrodes Pₖ₁ₓ, Pₖ₂ₓ are placed in the kerf regions Rx by decreasing coverage factors and placement rates in regions where the alignment marks are provided so as not to interfere with an alignment process performed after the bonding. The coverage factor of the bonding electrodes Pₖ₁ₓ in the kerf region R_{K} is calculated as a proportion of an area of the bonding electrodes Pₖ₁ₓ occupying an area of a unit region of the kerf region Rx. The placement rate of the bonding electrodes Pₖ₁ₓ in the kerf region Rx is calculated as (HA/HB)×100, where HA is the coverage factor of the bonding electrodes Pₖ₁ₓ placed in the kerf regions Rx of outer peripheries of the masks GM_{M}, GM_{P} and HB is the coverage factor in a case where the bonding electrodes Pₖ₁ₓ are placed on entire surfaces of the outer peripheries of the masks GM_{M}, GM_{P} excluding frame data regions.

With the designing method for the masks GM_{M}, GM_{P} according to the embodiment, since the bonding electrodes Pₖ₁ₓ, Pₖ₂ₓ can be placed in the kerf regions Rx of the wafers W_{M}, W_{P} considering a state where the step-and-repeat process or the step-and-scan process is performed, the placement rates can be improved. Accordingly, areas of the bonded surfaces S_{B} that can be planarized in the kerf regions Rx can be increased, and the occurrence of the voids can be reduced in the vicinity of boundaries between the device regions R_{MD} and the kerf regions Rx when the wafers W_{M}, W_{P} are bonded with the bonded surfaces S_{B}.

### OTHER EMBODIMENTS

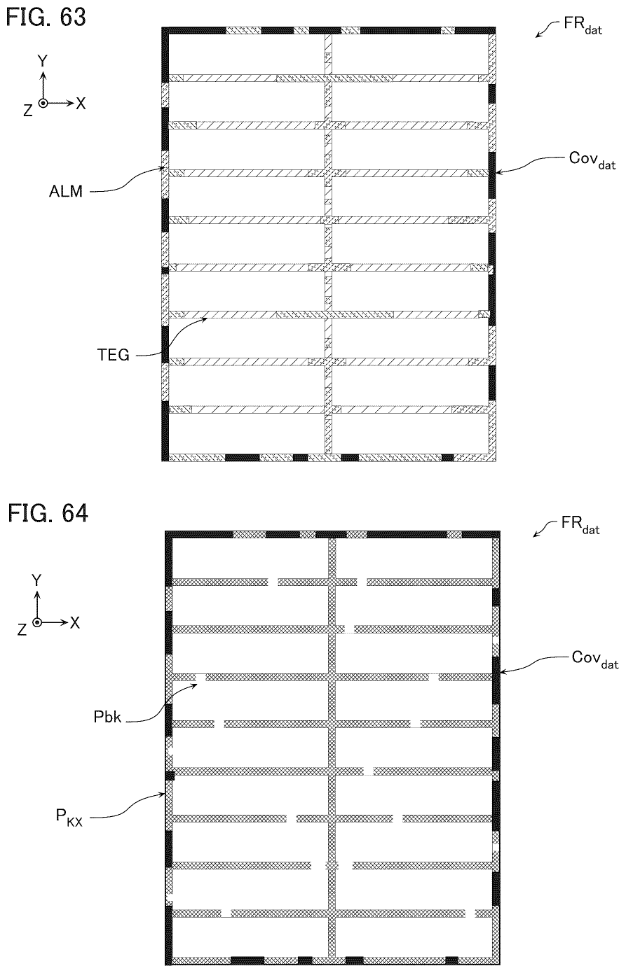

The designing method, the semiconductor device, and the mask set according to the embodiment have been described above. However, the designing method, the semiconductor device, and the mask set described above are merely examples, and specific configurations, and the like are appropriately adjustable. For example, while the masks GM_{M}, GM_{P} with 2×2 device regions and the frame data FR_{Mdat}, FR_{Pdat} with 2×2 or 6×6 device regions have been exemplified, the configuration of the device regions, the placement of the bonding electrodes, TEG, and lithography marks formed in the kerf regions Rx may be appropriately changed. For example, as illustrated in FIG. 63 and FIG. 64, the frame data FR_{dat} with 2×9 device regions may be used. Here, FIG. 63 is a plan view conceptually illustrating the frame data FR_{dat} in which frame data Cov_{dat}, lithography marks ALM, and

TEG according to a modification are placed. FIG. 64 is a plan view conceptually illustrating the frame data FR_{dat} in which the frame data Cov_{dat} and the bonding electrode patterns P_{KX} in the kerf region R_{K} according to a modification are placed. Note that a blank region Pbₖ in FIG. 64 indicates a region in which regions for lithography marks and TEG used at a back side are placed and the bonding electrode patterns P_{KX} are not placed.

In the embodiment, the example in which the NAND flash memory is mounted in the chip C_{M} as the semiconductor device has been described. However, the configuration of the semiconductor device is appropriately adjustable. For example, a 2D or 3D DRAM may be mounted or SRAM may be mounted in the chip C_{M}. When SRAM is mounted in the chip C_{M}, FinFET, Nano sheet, fork sheet, and the like may be used in the SRAM. Configurations other than the memory may be mounted in the chip C_{M}. For example, a plurality of Photo diodes and the like constituting an image pickup device and the like may be mounted in the chip C_{M}.

In the present specification, the following matter has been disclosed.

### [Matter 1]

A method of manufacturing a semiconductor device, the manufacturing method comprising:
using a first mask to transfer a plurality of first bonding electrode patterns to a first wafer;
forming a plurality of first bonding electrodes on the first wafer along the plurality of first bonding electrode patterns;
using a second mask to transfer a plurality of second bonding electrode patterns to a second wafer;
forming a plurality of second bonding electrode patterns on the second wafer along the plurality of second bonding electrode patterns; and
bonding the first wafer and the second wafer via the plurality of first bonding electrodes and the plurality of second bonding electrodes, wherein
the first mask includes:
   a plurality of first mask regions disposed at positions corresponding to a plurality of first device regions of the first wafer and including a plurality of first bonding electrode patterns corresponding to parts of the plurality of first bonding electrodes; and
   a second mask region disposed at a position corresponding to a first kerf region surrounding the first device regions and including a plurality of second bonding electrode patterns corresponding to other parts of the plurality of first bonding electrodes,
the second mask includes:
   a plurality of third mask regions disposed at positions corresponding to a plurality of second device regions of the second wafer and including a plurality of third bonding electrode patterns corresponding to parts of the plurality of second bonding electrodes; and
   a fourth mask region disposed at a position corresponding to a second kerf region surrounding the second device regions and including a plurality of fourth bonding electrode patterns corresponding to other parts of the plurality of second bonding electrodes,
the plurality of first bonding electrode patterns are disposed at positions that overlap with the plurality of third bonding electrode patterns, and
at least parts of the plurality of second bonding electrode patterns are disposed at positions that do not overlap with any of the plurality of fourth bonding electrode patterns.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A designing method of a mask set used for lithographic exposure in patterning a plurality of bonding electrodes in a first wafer and a second wafer that are bonded via the plurality of bonding electrodes, wherein
the mask set includes a first mask and a second mask,
each of the first wafer and the second wafer includes a plurality of device regions and a kerf region surrounding the plurality of device regions, and
the plurality of bonding electrodes includes a plurality of first bonding electrodes disposed in the device regions and a plurality of second bonding electrodes disposed in the kerf region, and each of the plurality of second bonding electrodes being in an electrically unconnected state, wherein
the designing method comprises:
specifying a size and a shape of the second bonding electrodes;
placing a plurality of second bonding electrode patterns corresponding to the second bonding electrodes in the kerf regions of the first mask and the second mask;
each unplaceable region is identified in each of the kerf region of the first mask and the kerf region of the second mask, the unplaceable region being a region where the second bonding electrode is unplaceable;
removing, in the kerf region of the first mask, the second bonding electrode patterns placed in the unplaceable region of the first mask;
generating a first pattern group in a lithographic exposure region adjacent to other lithographic exposure regions on both sides in a first direction and on both sides in a second direction intersecting with the first direction among nine or more lithographic exposure regions formed when the first mask is used to perform lithographic exposure three times or more while changing a position in the first direction and three times or more while changing a position in the second direction;
removing, in the kerf region of the second mask, the second bonding electrode patterns placed in the unplaceable region of the second mask;
generating a second pattern group in a lithographic exposure region adjacent to other lithographic exposure regions on both sides in the first direction and on both sides in the second direction among nine or more lithographic exposure regions formed when the second mask is used to perform lithographic exposure three times or more while changing a position in the first direction and three times or more while changing a position in the second direction; and
removing the second bonding electrode patterns placed in a non-overlapping section in each of the kerf region of the first mask and the kerf region of the second mask, the non-overlapping section being a plurality of positions of a plurality of the second bonding electrode patterns included in the first pattern group do not overlap with a plurality of positions of a plurality of the second bonding electrode patterns included in the second pattern group when viewed in a direction intersecting with front surfaces of the first wafer and the second wafer when the first wafer and the second wafer are bonded.

2. The designing method according to claim 1, wherein
each of the first mask and the second mask includes:
a plurality of mask regions corresponding to the plurality of device regions; and
a mask region corresponding to the kerf region, wherein
the mask region corresponding to the kerf region of the first mask includes:
a first region disposed between mask regions corresponding to a pair of the device regions adjacent in the first direction;
a second region disposed on one side in the first direction with respect to the plurality of mask regions corresponding to the plurality of device regions; and
a third region disposed on the other side in the first direction with respect to the plurality of mask regions corresponding to the plurality of device regions,
the mask region corresponding to the kerf region of the second mask includes:
a fourth region disposed between mask regions corresponding to a pair of the device regions adjacent in the first direction;
a fifth region disposed on one side in the first direction with respect to the plurality of mask regions corresponding to the plurality of device regions; and
a sixth region disposed on the other side in the first direction with respect to the plurality of mask regions corresponding to the plurality of device regions,
for the plurality of second bonding electrode patterns,
the plurality of second bonding electrode patterns disposed in the first region are disposed at positions that overlap with the plurality of fourth bonding electrode patterns disposed in the fourth region,
a plurality of second bonding electrode patterns in a pattern group obtained by combining the plurality of second bonding electrode patterns disposed in the second region and the plurality of second bonding electrode patterns disposed in the third region are disposed at positions that overlap with any of a plurality of fourth bonding electrode patterns in a pattern group obtained by combining the plurality of fourth bonding electrode patterns disposed in the fifth region and the plurality of fourth bonding electrode patterns disposed in the sixth region, and
at least parts of the plurality of second bonding electrode patterns disposed in the second region are disposed at positions that do not overlap with any of the plurality of fourth bonding electrode patterns disposed in the fifth region.

3. The designing method according to claim 2, wherein
at least parts of the plurality of second bonding electrode patterns disposed in the third region are disposed at positions that do not overlap with any of the plurality of fourth bonding electrode patterns disposed in the sixth region.

4. The designing method according to claim 2, wherein
the plurality of fourth bonding electrode patterns in the pattern group obtained by combining the plurality of fourth bonding electrode patterns disposed in the fifth region and the plurality of fourth bonding electrode patterns disposed in the sixth region are disposed at positions that overlap with any of the plurality of second bonding electrode patterns in the pattern group obtained by combining the plurality of second bonding electrode patterns disposed in the second region and the plurality of second bonding electrode patterns disposed in the third region, and
at least parts of the plurality of fourth bonding electrode patterns disposed in the fifth region are disposed at positions that do not overlap with any of the plurality of second bonding electrode patterns disposed in the second region.

5. The designing method according to claim 2, wherein
the unplaceable region of the first mask includes a first light-shielding region pattern,
a shape and an area of a pattern group obtained by combining a portion of the first light-shielding region pattern corresponding to the second region and a portion of the first light-shielding region pattern corresponding to the third region are same as a shape and an area of the second region and the third region,
the unplaceable region of the second mask includes a second light-shielding region pattern,
a shape and an area of a pattern group obtained by combining a portion of the second light-shielding region pattern corresponding to the fifth region and a portion of the second light-shielding region pattern corresponding to the sixth region are same as a shape and an area of the fifth region and the sixth region, and
a shape of the first light-shielding region pattern is different from a shape of the second light-shielding region pattern.

6. The designing method according to claim 5, wherein the unplaceable region of the first mask further includes a third light-shielding region pattern having a length in the first direction and a length in the second direction larger than a length in the first direction and a length in the second direction of the second bonding electrode patterns, respectively, and
the unplaceable region of the second mask further includes a fourth light-shielding region pattern having a length in the first direction and a length in the second direction larger than a length in the first direction and a length in the second direction of the second bonding electrode patterns, respectively.

7. A semiconductor device comprising
a first wafer and a second wafer bonded via a plurality of bonding electrodes, wherein
the first wafer includes:
a plurality of rectangular first device regions arranged in a first direction and a second direction intersecting with the first direction;
a plurality of first structure body regions arranged in the first direction or the second direction with respect to any of the plurality of first device regions;
a first kerf region surrounding each of the plurality of first device regions and the plurality of first structure body regions; and
a margin region where none of the plurality of first device regions, the plurality of first structure body regions, or the first kerf region is disposed,
the first device regions have outer peripheries away from an outer periphery of the first wafer,
a distance of the first device regions from the margin region is larger than one or both of a width in the first direction and a width in the second direction of the first device regions,
parts of the first structure body regions have outer peripheries along the outer periphery of the first wafer,
a distance of other parts of the first structure body regions from the margin region is smaller than the width in the first direction and the width in the second direction of the first device regions,
the first wafer includes:
an internal element; and
a first bonding electrode layer including parts of the plurality of bonding electrodes,
the first bonding electrode layer includes:
a plurality of first bonding electrodes disposed in the plurality of first device regions and the plurality of first structure body regions and electrically connected to the internal element; and
a plurality of second bonding electrodes disposed in the first kerf region and each being in an electrically unconnected state,
the second wafer includes:
a plurality of second device regions disposed at positions that overlap with the plurality of first device regions when viewed in a stacking direction intersecting with the first direction and the second direction;
a plurality of second structure body regions disposed at positions that overlap with the plurality of first structure body regions when viewed in the stacking direction; and
a second kerf region disposed at a position that overlaps with the first kerf region when viewed in the stacking direction,
the second wafer includes:
a plurality of transistors; and
a second bonding electrode layer disposed at a first wafer side and including other parts of the plurality of bonding electrodes,
the second bonding electrode layer includes:
a plurality of third bonding electrodes disposed in the plurality of second device regions and the plurality of second structure body regions and electrically connected to the plurality of transistors; and
a plurality of fourth bonding electrodes disposed in the second kerf region and each being in an electrically unconnected state,
the first kerf region includes:
a first region disposed between a pair of the first device regions adjacent in the first direction; and
a second region disposed between any of the plurality of first structure body regions and the margin region,
the second kerf region includes:
a third region disposed at a position that overlaps with the first region when viewed in the stacking direction; and
a fourth region disposed at a position that overlaps with the second region when viewed in the stacking direction,
a plurality of second bonding electrodes disposed in the first region are disposed at positions that overlap with any of a plurality of fourth bonding electrodes disposed in the third region when viewed in the stacking direction, and
at least parts of a plurality of second bonding electrodes disposed in the second region are disposed at positions that do not overlap with any of a plurality of fourth bonding electrodes disposed in the fourth region when viewed in the stacking direction.

8. The semiconductor device according to claim 7, wherein
the first kerf region includes one or both of a lithography mark and a test element group, and
the plurality of bonding electrodes are disposed at positions that do not overlap with one or both of the lithography mark and the test element group when viewed in the stacking direction.

9. The semiconductor device according to claim 7, wherein
the first kerf region includes a lithography mark, and
the plurality of bonding electrodes are disposed at positions that overlap with the lithography mark when viewed in the stacking direction.

10. The semiconductor device according to claim 7, wherein
the plurality of fourth bonding electrodes disposed in the third region are disposed at positions that overlap with any of the plurality of second bonding electrodes disposed in the first region when viewed in the stacking direction, and
at least parts of the plurality of fourth bonding electrodes disposed in the fourth region are disposed at positions that do not overlap with any of the plurality of second bonding electrodes disposed in the second region when viewed in the stacking direction.

11. The semiconductor device according to claim 7, wherein
a plurality of first structure body regions having a part of an outer periphery thereof along outer peripheries of the first wafer and the second wafer has a smaller area than the first device regions.

12. The semiconductor device according to claim 11, wherein
other parts of the plurality of first structure body regions are in a rectangular shape and have a same area as the first device regions.

13. The semiconductor device according to claim 7, wherein
the first wafer further includes:
a plurality of first conductive layers stacked in a stacking direction; and
a first wiring layer disposed between the plurality of first conductive layers and the first bonding electrode layer,
the first kerf region includes:
a region including a plurality of second conductive layers stacked in the stacking direction corresponding to the plurality of first conductive layers; and
an outer region of the region including the plurality of second conductive layers, and
on the first wiring layer, a coverage factor of a wiring disposed in the region including the plurality of second conductive layers is smaller than a coverage factor of a wiring disposed in the outer region.

14. The semiconductor device according to claim 7, wherein
the first wafer further includes a plurality of first conductive layers stacked in a stacking direction,
the second wafer further includes a second wiring layer disposed between the plurality of transistors and the second bonding electrode layer,
the first kerf region includes:
a region including a plurality of second conductive layers stacked in the stacking direction corresponding to the plurality of first conductive layers; and
an outer region of the region including the plurality of second conductive layers, and
on the second wiring layer, a coverage factor of a wiring disposed in the region including the plurality of second conductive layers is smaller than a coverage factor of a wiring disposed in the outer region.

15. A mask set used for lithographic exposure in patterning a plurality of bonding electrodes in a first wafer and a second wafer that are bonded via the plurality of bonding electrodes, the mask set comprising
a first mask and a second mask, wherein
the first mask includes:
a plurality of first mask regions disposed at positions corresponding to a plurality of first device regions of the first wafer and including a plurality of first bonding electrode patterns corresponding to parts of the plurality of bonding electrodes; and
a second mask region disposed at a position corresponding to a first kerf region surrounding the first device regions and including a plurality of second bonding electrode patterns corresponding to others of the plurality of bonding electrodes,
the second mask includes:
a plurality of third mask regions disposed at positions corresponding to a plurality of second device regions of the second wafer and including a plurality of third bonding electrode patterns corresponding to other parts of the plurality of bonding electrodes; and
a fourth mask region disposed at a position corresponding to a second kerf region surrounding the second device regions and including a plurality of fourth bonding electrode patterns corresponding to others of the plurality of bonding electrodes,
the plurality of first bonding electrode patterns are disposed at positions that overlap with the plurality of third bonding electrode patterns, and
at least parts of the plurality of second bonding electrode patterns are disposed at positions that do not overlap with any of the plurality of fourth bonding electrode patterns.

16. The mask set according to claim 15, wherein
the second mask region includes:
a first region disposed between a pair of first mask regions adjacent in a first direction;
a second region disposed on one side in the first direction with respect to the plurality of first mask regions; and
a third region disposed on the other side in the first direction with respect to the plurality of first mask regions,
the fourth mask region includes:
a fourth region disposed between a pair of third mask regions adjacent in the first direction;
a fifth region disposed on the other side in the first direction with respect to the plurality of third mask regions; and
a sixth region disposed on the one side in the first direction with respect to the plurality of third mask regions,
for the plurality of second bonding electrode patterns,
the plurality of second bonding electrode patterns disposed in the first region are disposed at positions that overlap with the plurality of fourth bonding electrode patterns disposed in the fourth region,
a plurality of second bonding electrode patterns in a pattern group obtained by combining the plurality of second bonding electrode patterns disposed in the second region and the plurality of second bonding electrode patterns disposed in the third region are disposed at positions that overlap with any of a plurality of fourth bonding electrode patterns in a pattern group obtained by combining the plurality of fourth bonding electrode patterns disposed in the fifth region and the plurality of fourth bonding electrode patterns disposed in the sixth region, and
at least parts of the plurality of second bonding electrode patterns disposed in the second region are disposed at positions that do not overlap with any of the plurality of fourth bonding electrode patterns disposed in the fifth region.

17. The mask set according to claim 16, wherein
at least parts of the plurality of second bonding electrode patterns disposed in the third region are disposed at positions that do not overlap with any of the plurality of fourth bonding electrode patterns disposed in the sixth region.

18. The mask set according to claim 16, wherein
the plurality of fourth bonding electrode patterns in the pattern group obtained by combining the plurality of fourth bonding electrode patterns disposed in the fifth region and the plurality of fourth bonding electrode patterns disposed in the sixth region are disposed at positions that overlap with any of the plurality of second bonding electrode patterns in the pattern group obtained by combining the plurality of second bonding electrode patterns disposed in the second region and the plurality of second bonding electrode patterns disposed in the third region, and
at least parts of the plurality of fourth bonding electrode patterns disposed in the fifth region are disposed at positions that do not overlap with any of the plurality of second bonding electrode patterns disposed in the second region.

19. The mask set according to claim 16, wherein
for the plurality of second bonding electrode patterns, the plurality of second bonding electrode patterns disposed in the second region are disposed at positions that do not overlap with any of the plurality of second bonding electrode patterns disposed in the third region when the pattern group is generated by combining the plurality of second bonding electrode patterns disposed in the second region and the plurality of second bonding electrode patterns disposed in the third region.

20. The mask set according to claim 16, wherein
the first mask includes a first light-shielding region that does not include any of the plurality of second bonding electrode patterns,
a shape and an area of a region obtained by combining a portion of the first light-shielding region corresponding to the second region and a portion of the first light-shielding region corresponding to the third region are same as a shape and an area of the second region and the third region,
the second mask includes a second light-shielding region that does not include any of the plurality of fourth bonding electrode patterns,
a shape and an area of a region obtained by combining a portion of the second light-shielding region corresponding to the fifth region and a portion of the second light-shielding region corresponding to the sixth region are same as a shape and an area of the fifth region and the sixth region, and
at least a part of the portion of the first light-shielding region corresponding to the second region is disposed at a position that does not overlap with at least a part of the portion of the second light-shielding region corresponding to the fifth region.
